(19) United States
(12) Patent Application Publication
(10) Pub. No.: US 2026/0190485 A1
(43) Pub. Date: Jul. 2, 2026

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Jianpeng WU, Beijing (CN); Mengqi WANG, Beijing (CN); Wenhui GAO, Beijing (CN); Lang LIU, Beijing (CN); Hongbo MA, Beijing (CN)

(21) Appl. No.: 18/836,007

(22) PCT Filed: Apr. 19, 2023
(86) PCT No.: PCT/CN2023/089333

§ 371 Date: Aug. 6, 2024

(51) Int. Cl. H10D 86/40; H10D 86/01; H10D 86/60; H10K 59/121; H10K 59/126

(52) U.S. Cl. CPC H10D 86/441; H10D 86/021; H10D 86/481; H10D 86/60; H10K 59/126; H10K 59/1213; H10K 59/1216

(57) ABSTRACT

A display substrate includes a plurality of circuit units, wherein a circuit unit includes a pixel drive circuit, and the pixel drive circuit at least includes a plurality of transistors. In a plane perpendicular to the display substrate, the circuit unit includes a semiconductor layer disposed on a substrate, the semiconductor layer at least includes a first active pattern and a second active pattern, the first active pattern includes an active layer of at least one transistor, the second active pattern includes an active layer of at least one transistor.

### CROSS-REFERENCE TO RELATED APPLICATION

This application is a national stage application of PCT Application No. PCT/CN2023/089333, which is filed on Apr. 19, 2023 and entitled “Display Substrate, Manufacturing Method Therefor, and Display Apparatus”, the content of which should be regarded as being incorporated herein by reference.

### TECHNICAL FIELD

The present disclosure relates to, but is not limited to, the field of display technologies, and particularly to a display substrate and a manufacturing method therefor, and a display apparatus.

### BACKGROUND

Organic Light Emitting Diodes (OLED's) and Quantum dot Light Emitting Diodes (QLED's) are active light emitting display devices and have advantages such as self-luminescence, a wide viewing angle, a high contrast ratio, low power consumption, an extremely high response speed, lightness and thinness, flexibility, and a low cost. With constant development in display technologies, a flexible display that uses an OLED or a QLED as a light emitting device and performs signal control by a Thin Film Transistor (TFT) has become the majority in the field of display at present.

### SUMMARY

The following is a summary of subject matters described herein in detail. This summary is not intended to limit the protection scope of claims.

In one aspect, the present disclosure provides a display substrate including a plurality of circuit units forming a plurality of unit rows and a plurality of unit columns, wherein at least one circuit unit includes a pixel drive circuit including at least a plurality of transistors; in a plane perpendicular to the display substrate, at least one circuit unit includes a semiconductor layer disposed on a substrate and a plurality of conductive layers disposed on a side of the semiconductor layer away from the substrate, the semiconductor layer at least includes active layers of a plurality of transistors, the semiconductor layer at least includes a first active pattern and a second active pattern, the first active pattern includes an active layer of at least one transistor, the second active pattern includes an active layer of at least one transistor; in at least one circuit unit, the first active pattern is spaced from the second active pattern, active layers of a plurality of transistors in the circuit unit are spaced from active layers of a plurality of transistors in a circuit unit adjacent in a unit row direction, and active layers of a plurality of transistors in the circuit unit are spaced from active layers of a plurality of transistors in a circuit unit adjacent in a unit column direction.

In an exemplary implementation, the first active pattern includes active layers of two transistors, and the active layers of the two transistors are connected to each other to form an integral structure; the second active pattern includes active layers of seven transistors, and the active layers of the seven transistors are connected to each other to form an integral structure.

In an exemplary implementation, the pixel drive circuit includes a first transistor and a seventh transistor as initialization transistors, a second transistor as a compensation transistor, a third transistor as a drive transistor, a fourth transistor as a data writing transistor, a fifth transistor and a sixth transistor as light emitting transistors, and an eighth transistor and a ninth transistor as reference transistors. The first active pattern includes an active layer of the fourth transistor and an active layer of the ninth transistor, and the second active pattern includes active layers of the first to third transistors and active layers of the fifth to eighth transistors.

In an exemplary implementation, the pixel drive circuit further includes a first storage capacitor and a second storage capacitor; the first storage capacitor at least includes a first plate and a third plate, an orthographic projection of the first plate on the substrate is overlapped, at least partially, with an orthographic projection of the third plate on the substrate; the second storage capacitor at least includes a second plate and a fourth plate, an orthographic projection of the second plate on the substrate is overlapped, at least partially, with an orthographic projection of the fourth plate on the substrate; the first plate serves as a gate electrode of the third transistor, the second plate is connected with the third plate, and the fourth plate is connected with a first power supply line.

In an exemplary implementation, the plurality of conductive layers at least include a first conductive layer, a second conductive layer, a third conductive layer, and a fourth conductive layer disposed sequentially along a direction away from the substrate; the first plate and the second plate are disposed in the first conductive layer, the third plate and the fourth plate are disposed in the second conductive layer, the first power supply line is disposed in the fourth conductive layer, and the second plate is connected with the third plate through a connection electrode disposed in the third conductive layer.

In an exemplary implementation, the third plate is provided with a first plate connection line extending toward the fourth plate, the fourth plate is provided with a first groove recessed in a direction away from the third plate, the first plate connection line is disposed within the first groove, and an end of the first plate connection line away from the third plate is connected with the connection electrode through a via.

In an exemplary implementation, the pixel drive circuit further includes an additional capacitor, and a lower plate of the additional capacitor is disposed in the semiconductor layer, an upper plate of the additional capacitor is disposed in the second conductive layer, an orthographic projection of the upper plate on the substrate is overlapped, at least partially, with an orthographic projection of the lower plate on the substrate, the lower plate is connected with the second plate, and the upper plate is connected with the fourth plate.

In an exemplary implementation, the lower plate includes a second region of the active layer of the fourth transistor, the second plate is connected with the second region of the active layer of the fourth transistor through the connection electrode disposed in the third conductive layer, and the upper plate and the fourth plate are connected to each other to form an integral structure.

In an exemplary implementation, a gate electrode of the first transistor is connected with a fourth scan signal line, a gate electrode of the second transistor is connected with a fifth scan signal line, a gate electrode of the fourth transistor is connected with a third scan signal line, a gate electrode of the fifth transistor and a gate electrode of the sixth transistor are connected with a light emitting signal line, a gate electrode of the seventh transistor and a gate electrode of the eighth transistor are connected with a first scan signal line, a gate electrode of the ninth transistor is connected with a second scan signal line, and the second scan signal line and the fifth scan signal line output a same scan signal.

In an exemplary implementation, the display substrate further includes a second scan connection line, the second scan signal line and the second scan connection line are disposed in different conductive layers, an orthographic projection of the second scan signal line on the substrate is overlapped, at least partially, with an orthographic projection of the second scan connection line on the substrate, and the second scan signal line is connected with the second scan connection line through a via to form scan signal lines in a double-layer structure.

In an exemplary implementation, the plurality of conductive layers at least include a first conductive layer, a second conductive layer, a third conductive layer, and a fourth conductive layer disposed sequentially along a direction away from the substrate; the second scan connection line is disposed in the first conductive layer, and the second scan signal line is disposed in the third conductive layer.

In an exemplary implementation, the display substrate further includes a fifth scan connection line, the fifth scan signal line and the fifth scan connection line are disposed in different conductive layers, an orthographic projection of the fifth scan signal line on the substrate is overlapped, at least partially, with an orthographic projection of the fifth scan connection line on the substrate, and the fifth scan signal line is connected with the fifth scan connection line through a via to form scan signal lines in a double-layer structure.

In an exemplary implementation, the plurality of conductive layers at least include a first conductive layer, a second conductive layer, a third conductive layer, and a fourth conductive layer disposed sequentially along the direction away from the substrate; the fifth scan connection line is disposed in the second conductive layer, and the fifth scan signal line is disposed in the third conductive layer.

In an exemplary implementation, at least one circuit unit further includes a first shield electrode, an orthographic projection of the first shield electrode on the substrate is overlapped, at least partially, with an orthographic projection of a semiconductor layer between two gate electrodes of the first transistor on the substrate, and the orthographic projection of the first shield electrode on the substrate is overlapped, at least partially, with an orthographic projection of a semiconductor layer between two gate electrodes of the second transistor on the substrate.

In an exemplary implementation, at least one circuit unit further includes a second shield electrode, an orthographic projection of the second shield electrode on the substrate is overlapped, at least partially, with orthographic projections of a second electrode of the fourth transistor and a second electrode of the ninth transistor on the substrate.

In an exemplary implementation, at least one circuit unit further includes a third shield electrode, an orthographic projection of the third shield electrode on the substrate is overlapped, at least partially, with an orthographic projection of a semiconductor layer between two gate electrodes of the fourth transistor on the substrate.

In an exemplary implementation, at least one circuit unit further includes a fourth shield electrode, an orthographic projection of the fourth shield electrode on the substrate is overlapped, at least partially, with an orthographic projection of a semiconductor layer between two gate electrodes of the ninth transistor on the substrate.

In an exemplary implementation, the display substrate further includes at least one first power supply connection line extending along the unit row direction, and at least one first power supply line extending along the unit column direction; the first power supply line and the first power supply connection line are disposed in different conductive layers, and the first power supply line and the first power supply connection line are connected through a via to form a mesh structure for transmitting a first power supply signal.

In an exemplary implementation, the display substrate further includes at least one second power supply connection line extending along the unit row direction, and at least one second power supply line extending along the unit column direction; the second power supply line and the second power supply connection line are disposed in different conductive layers, and the second power supply line and the second power supply connection line are connected through a via to form a mesh structure for transmitting a second power supply signal.

In an exemplary implementation, the display substrate further includes at least one reference signal connection line extending along the unit row direction, and at least one reference signal line extending along the unit column direction; the reference signal line and the reference signal connection line are disposed in different conductive layers, and the reference signal connection line are connected with the reference signal line through a via to form a mesh structure for transmitting a reference signal.

In another aspect, the present disclosure also provides a display apparatus, including the display substrate described above.

In yet another aspect, the present disclosure also provides a method for manufacturing a display substrate, wherein the display substrate includes a plurality of circuit units forming a plurality of unit rows and a plurality of unit columns, at least one circuit unit includes a pixel drive circuit, the pixel drive circuit at least includes a plurality of transistors; the manufacturing method includes:

forming a semiconductor layer on a substrate, and a plurality of conductive layers disposed on a side of the semiconductor layer away from the substrate wherein the semiconductor layer at least includes active layers of a plurality of transistors, the semiconductor layer includes at least a first active pattern and a second active pattern, the first active pattern includes an active layer of at least one transistor, and the second active pattern includes an active layer of at least one transistor, the second active pattern including an active layer of at least one transistor. In at least one circuit unit, the first active pattern is spaced from the second active pattern, the active layers of the plurality of transistors in the circuit unit are spaced from active layers of a plurality of transistors in a circuit unit adjacent in a unit row direction, and the active layers of the plurality of transistors in the circuit unit are spaced from active layers of a plurality of transistors in a circuit unit adjacent in a unit column direction.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display apparatus.

FIG. 2 is a schematic diagram of a planar structure of a display substrate.

FIG. 3 illustrates a schematic diagram of a sectional structure of a display substrate.

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is a schematic diagram of a structure of a semiconductor layer in FIG. 5.

FIG. 7 is a schematic diagram of a regional structure of a first storage capacitor and a second storage capacitor in FIG. 5.

FIG. 8 is a schematic diagram of a display substrate after a pattern of a semiconductor layer is formed, according to the present disclosure.

FIGS. 9A and 9B are schematic diagrams of a display substrate after a pattern of a first conductive layer is formed, according to the present disclosure.

FIGS. 10A and 10B are schematic diagrams of a display substrate after a pattern of a second conductive layer is formed, according to the present disclosure.

FIG. 11 is a schematic diagram of a display substrate after a pattern of a fourth insulation layer is formed, according to the present disclosure.

FIG. 12A and FIG. 12B are schematic diagrams of a display substrate after a pattern of a third conductive layer is formed, according to the present disclosure.

FIG. 13 is a schematic diagram of a display substrate after a pattern of a fifth insulation layer is formed, according to the present disclosure.

FIGS. 14A and 14B are schematic diagrams of a display substrate after a pattern of a fourth conductive layer is formed, according to the present disclosure.

FIG. 15 illustrates a schematic diagram of a planar structure of another display substrate according to an exemplary embodiment of the present disclosure.

FIG. 16 is a schematic diagram of a structure of a second scan signal line and a fifth scan signal line in FIG. 15.

FIG. 17 is a schematic diagram of another display substrate after a pattern of a semiconductor layer is formed, according to the present disclosure.

FIGS. 18A and 18B are schematic diagrams of another display substrate after a pattern of a first conductive layer is formed, according to the present disclosure.

FIGS. 19A and 19B are schematic diagrams of another display substrate after a pattern of a second conductive layer is formed, according to the present disclosure.

FIG. 20 is a schematic diagram of another display substrate after a pattern of a fourth insulation layer is formed, according to the present disclosure.

FIGS. 21A and 21B are schematic diagrams of another display substrate after a pattern of a third conductive layer is formed, according to the present disclosure.

FIG. 22 is a schematic diagram of another display substrate after a pattern of a fifth conductive layer is formed, according to the present disclosure.

FIGS. 23A and 23B are schematic diagrams of another display substrate after a pattern of a fourth conductive layer is formed, according to the present disclosure.

### DESCRIPTION OF REFERENCE NUMBERS

10—first active pattern; 11—first active layer; 12—second active layer; 13—third active layer; 14—fourth active layer; 15—fifth active layer; 16—sixth active layer; 17—seventh active layer; 18—eighth active layer; 19—ninth active layer; 20—second active pattern; 21—first gate electrode; 22—second gate electrode; 24—fourth gate electrode; 25—fifth gate electrode; 26—sixth gate electrode; 29—ninth gate electrode; 31—first light emitting signal line; 32—second light emitting signal line; 33—repair line; 36—first shield electrode; 37—second shield electrode; 38—third shield electrode; 39—fourth shield electrode; 41—first connection electrode; 42—second connection electrode; 43—third connection electrode; 44—fourth connection electrode; 45—fifth connection electrode; 46—sixth connection electrode; 47—seventh connection electrode; 48—eighth connection electrode; 51—first power supply line; 52—second power supply line; 53—data signal line; 54—reference signal connection line; 55—anode connection electrode; 61—first scan signal line; 62—second scan signal line; 62-1—second scan connection line; 63—third scan signal line; 64—fourth scan signal line; 65—fifth scan signal line; 65-1—fifth scan connection line; 68—first power supply connection line; 69—second power supply connection line; 71—first plate; 72—second plate; 73—third plate; 74—fourth plate; 75—first opening; 76—second opening; 81—first initial signal line; 82—second initial signal line; 91—first reference signal line; 92—second reference signal line; 101—substrate; 102—drive circuit layer; 103—light emitting structure layer; 104—encapsulation structure layer.

### DETAILED DESCRIPTION

To make the objectives, technical solutions, and advantages of the present disclosure clearer, the embodiments of the present disclosure will be described in detail below with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three ends, i.e., a gate electrode, a drain electrode, and a source electrode. The transistor has a channel region between the drain electrode (drain electrode end, drain region, or drain) and the source electrode (source electrode end, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source end” and the “drain end”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

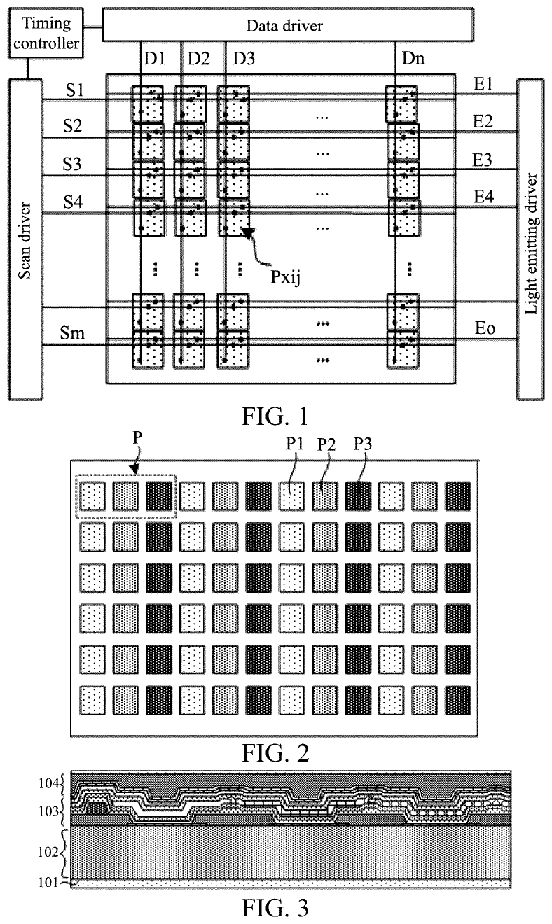

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively. The light emitting unit may include a light emitting device connected to the pixel drive circuit of the circuit unit. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

FIG. 2 is a schematic diagram of a planar structure of a display substrate. In an exemplary embodiment, the display substrate may include a display region and a bezel region located on a periphery of the display region. As shown in FIG. 2, the display region of the display substrate may include a plurality of pixel units P arranged in a matrix. At least one of the pixel units P may include a first sub-pixel P1 emitting light in a first color, a second sub-pixel P2 emitting light in a second color, and a third sub-pixel P3 emitting light in a third color. Each sub-pixel may include a circuit unit and a light emitting unit. The circuit unit may at least include a pixel drive circuit, the pixel drive circuit is connected with a scan signal line, a data signal line, and a light emitting signal line, respectively, and is configured to receive a data voltage transmitted by the data signal line and output a corresponding current to the light emitting device under control of the scan signal line and the light emitting signal line. The light emitting unit may at least include a light emitting device. The light emitting device is correspondingly connected with the pixel drive circuit of the sub-pixel where the light emitting device is located. The light emitting device is configured to emit light with a corresponding brightness in response to a current output by the pixel drive circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a delta-shaped arrangement, etc., which is not limited here in the present disclosure.

In an exemplary implementation, a pixel unit may include four sub-pixels, and the four sub-pixels may be arranged in a manner to stand side by side horizontally, in a manner to stand side by side vertically, or in a manner of a square, which is not limited here in the present disclosure.

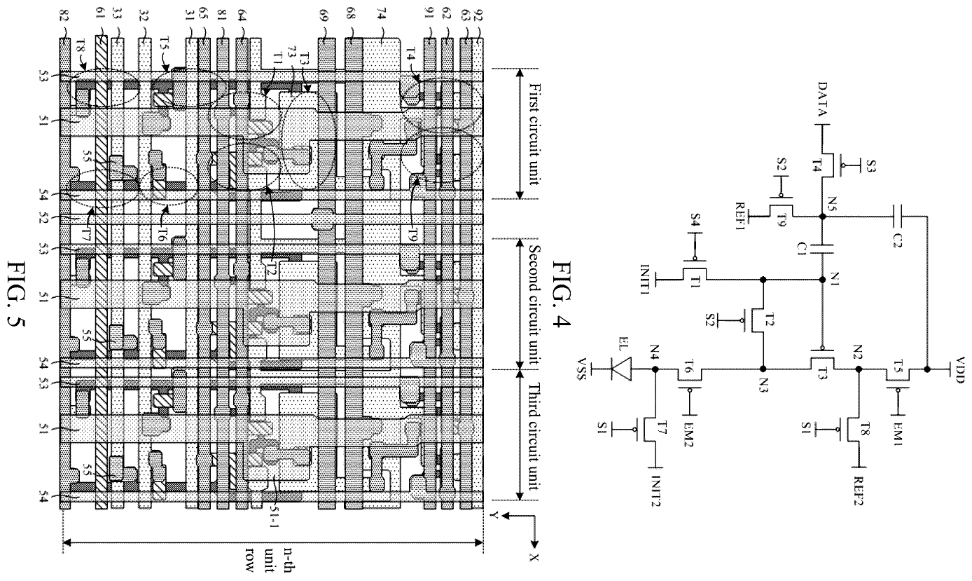

FIG. 3 illustrates schematically a sectional view of a structure of a display substrate, which illustrates a structure of three sub-pixels of the display substrate. As shown in FIG. 3, in a plane perpendicular to the display substrate, a display region of the display substrate may include a drive circuit layer 102 disposed on a substrate 101, a light emitting structure layer 103 disposed on a side of the drive circuit layer 102 away from the substrate 101, and an encapsulation structure layer 104 disposed on a side of the light emitting structure layer 103 away from the substrate 101. In some possible implementations, the display substrate may include another film, such as a touch structure layer, which is not limited here in the present disclosure.

In an exemplary implementation, the substrate 101 may be a flexible substrate, or may be a rigid substrate. The drive circuit layer 102 may include a plurality of circuit units, wherein a circuit unit may at least include a pixel drive circuit, and the pixel drive circuit may include a plurality of transistors and a storage capacitor. The light emitting structure layer 103 may include a plurality of light emitting units, wherein a light emitting unit may at least include a light emitting device, and the light emitting device may include an anode, an organic light emitting layer, and a cathode. The anode is connected with a pixel drive circuit. The organic light emitting layer is connected with the anode. The cathode is connected with the organic light emitting layer. The organic light emitting layer is driven by the anode and the cathode to emit light in a corresponding color. The encapsulation structure layer 104 may include a first encapsulation layer, a second encapsulation layer, and a third encapsulation layer that are stacked, wherein the first encapsulation layer and the third encapsulation layer may be made of an inorganic material, the second encapsulation layer may be made of an organic material, and the second encapsulation layer is disposed between the first encapsulation layer and the third encapsulation layer to form a laminated structure of an inorganic material/an organic material/an inorganic material, which ensures that external water vapor cannot enter the light emitting structure layer 103.

In an exemplary implementation, the organic light emitting layer may include an Emitting Layer (EML), and any one or more of the following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL).

A display substrate is provided in an exemplary embodiment of the present disclosure, which includes a plurality of circuit units forming a plurality of unit rows and a plurality of unit columns, wherein at least one circuit unit includes a pixel drive circuit including at least a plurality of transistors. In a plane perpendicular to the display substrate, at least one circuit unit includes a semiconductor layer disposed on a substrate, and a plurality of conductive layers disposed on a side of the semiconductor layer away from the substrate, wherein the semiconductor layer at least includes an active layer of a plurality of transistors. The semiconductor layer includes, at least, a first active pattern and a second active pattern, wherein the first active pattern includes an active layer of at least one transistor, the second active pattern includes an active layer of at least one transistor. In at least one circuit unit, the first active pattern is spaced from the second active pattern, an active layer of a plurality of transistors in the circuit unit is spaced from an active layer of a plurality of transistors in a circuit unit adjacent in a unit row direction, and an active layer of a plurality of transistors in the circuit unit is spaced from an active layer of a plurality of transistors in a circuit unit adjacent in a unit column direction.

In an exemplary implementation, the first active pattern includes active layers of two transistors, and the active layers of the two transistors are connected to each other to form an integral structure; the second active pattern includes active layers of seven transistors, and the active layers of the seven transistors are connected to each other to form an integral structure.

In an exemplary implementation, the pixel drive circuit includes a first transistor and a seventh transistor as initialization transistors, a second transistor as a compensation transistor, a third transistor as a drive transistor, a fourth transistor as a data writing transistor, a fifth transistor and a sixth transistor as light emitting transistors, and an eighth transistor and a ninth transistor as reference transistors. The first active pattern includes an active layer of the fourth transistor and an active layer of the ninth transistor, and the second active pattern includes active layers of the first to third transistors and active layers of the fifth to eighth transistors.

In an exemplary implementation, the pixel drive circuit further includes a first storage capacitor and a second storage capacitor; the first storage capacitor at least includes a first plate and a third plate, an orthographic projection of the first plate on the substrate is overlapped, at least partially, with an orthographic projection of the third plate on the substrate; the second storage capacitor at least includes a second plate and a fourth plate, an orthographic projection of the second plate on the substrate is overlapped, at least partially, with an orthographic projection of the fourth plate on the substrate; the first plate serves as a gate electrode of the third transistor, the second plate is connected with the third plate, and the fourth plate is connected with a first power supply line.

In an exemplary implementation, the pixel drive circuit further includes an additional capacitor, a lower plate of the additional capacitor is disposed in the semiconductor layer, an upper plate of the additional capacitor is disposed in the second conductive layer, an orthographic projection of the upper plate on the substrate is overlapped, at least partially, with an orthographic projection of the lower plate on the substrate, the lower plate is connected with the second plate, and the upper plate is connected with the fourth plate.

In an exemplary embodiment, a gate electrode of the ninth transistor is connected with a second scan signal line, a gate electrode of the second transistor is connected with a fifth scan signal line, and the second scan signal line and the fifth scan signal line output a same scan signal.

In an exemplary implementation, the display substrate further includes a second scan connection line, the second scan signal line and the second scan connection line are disposed in different conductive layers, an orthographic projection of the second scan signal line on the substrate is overlapped, at least partially, with an orthographic projection of the second scan connection line on the substrate, and the second scan signal line is connected with the second scan connection line through a via to form scan signal lines in a double-layer structure.

In an exemplary implementation, the plurality of conductive layers at least include a first conductive layer, a second conductive layer, a third conductive layer, and a fourth conductive layer disposed sequentially along a direction away from the substrate; the second scan connection line is disposed in the first conductive layer, and the second scan signal line is disposed in the third conductive layer.

In an exemplary implementation, the display substrate further includes a fifth scan connection line, the fifth scan signal line and the fifth scan connection line are disposed in different conductive layers, an orthographic projection of the fifth scan signal line on the substrate is overlapped, at least partially, with an orthographic projection of the fifth scan connection line on the substrate, and the fifth scan signal line is connected with the fifth scan connection line through a via to form scan signal lines in a double-layer structure.

In an exemplary implementation, the plurality of conductive layers at least include a first conductive layer, a second conductive layer, a third conductive layer, and a fourth conductive layer disposed sequentially along the direction away from the substrate; the fifth scan connection line is disposed in the second conductive layer, and the fifth scan signal line is disposed in the third conductive layer.

In an exemplary implementation, at least one circuit unit further includes a first shield electrode, an orthographic projection of the first shield electrode on the substrate is overlapped, at least partially, with an orthographic projection of a semiconductor layer between two gate electrodes of the first transistor on the substrate, and the orthographic projection of the first shield electrode on the substrate is overlapped, at least partially, with an orthographic projection of a semiconductor layer between two gate electrodes of the second transistor on the substrate.

In an exemplary implementation, at least one circuit unit further includes a second shield electrode, an orthographic projection of the second shield electrode on the substrate is overlapped, at least partially, with orthographic projections of a second electrode of the fourth transistor and a second electrode of the ninth transistor on the substrate.

In an exemplary implementation, at least one circuit unit further includes a third shield electrode, an orthographic projection of the third shield electrode on the substrate is overlapped, at least partially, with an orthographic projection of a semiconductor layer between two gate electrodes of the fourth transistor on the substrate.

In an exemplary implementation, at least one circuit unit further includes a fourth shield electrode, an orthographic projection of the fourth shield electrode on the substrate is overlapped, at least partially, with an orthographic projection of a semiconductor layer between two gate electrodes of the ninth transistor on the substrate.

The display substrate in the present disclosure is illustrated with examples below through some exemplary embodiments.

FIG. 4 is an equivalent circuit diagram of a pixel drive circuit according to an exemplary embodiment of the present disclosure. In an exemplary implementation, the pixel drive circuit may be of a structure of 3T1C, 4T1C, 5T1C, 5T2C, 6T1C, 7T1C, 8T1C or 9T2C. As shown in FIG. 4, the pixel drive circuit according to the exemplary embodiment of the present disclosure may be of a 9T2C structure, and may include nine transistors (a first transistor T1 to a ninth transistor T9) and two storage capacitors (a first storage capacitor C1 and a second storage capacitor C2), and the pixel drive circuit is connected to 12 signal lines (a first scan signal line S1, a second scan signal line S2, a third scan signal line S3, a fourth scan signal line S4, a first light emitting signal line EM1, a second light emitting signal line EM2, a first initial signal line INIT1, a second initial signal line INIT2, a first reference signal line REF1, a second reference signal line REF2, a data signal line DATA and a first power supply line VDD), respectively.

In an exemplary implementation, the pixel drive circuit may include a first node N1, a second node N2, a third node N3, a fourth node N4, and a fifth node N5. The first node N1 is connected to a second electrode of the first transistor, a first electrode of the second transistor T2, a gate electrode of the third transistor T3, and a first electrode of the first storage capacitor C1, respectively. The second node N2 is connected to a first electrode of the third transistor T3, a second electrode of the eighth transistor T8, and a second electrode of the fifth transistor T5, respectively. The third node N3 is connected to a second electrode of the second transistor T2, a second electrode of the third transistor T3, and a first electrode of the sixth transistor T6, respectively. The fourth node N4 is connected to a second electrode of the sixth transistor T6, and a second electrode of the seventh transistor T7, respectively. The fifth node N5 is connected to a second electrode of the fourth transistor T4, a second electrode of the ninth transistor T9, a second end of the first storage capacitor C1, and a second end of the second storage capacitor C2, respectively.

In an exemplary implementation, the first end of the first storage capacitor C1 is connected with the first node N1, the second end of the first storage capacitor C1 is connected with the fifth node N5, a first end of the second storage capacitor C2 is connected with the first power supply line VDD, and the second end of the second storage capacitor C2 is connected with the fifth node N5.

In an exemplary implementation, a gate electrode of the first transistor T1 is connected with the fourth scan signal line S4, a first electrode of the first transistor T1 is connected with the first initial signal line INIT1, and the second electrode of the first transistor is connected with the first node N1. When an ON level signal is applied to the fourth scan signal line S4, the first transistor T1 transmits a first initial voltage to the gate electrode of the third transistor T3 and the first end of the first storage capacitor C1, thereby releasing charges accumulated in the first storage capacitor C1 and achieving initialization.

In an exemplary implementation, a gate electrode of the second transistor T2 is connected to the second scan signal line S2, the first electrode of the second transistor T2 is connected to the first node N1, and the second electrode of the second transistor T2 is connected to the third node N3. When an ON level signal is applied to the second scan signal line S2, the second transistor T2 enables the gate electrode of the third transistor T3 to be connected with the second electrode of the third transistor T3.

In an exemplary implementation, the gate electrode of the third transistor T3 is connected with the first node N1. That is, the gate electrode of the third transistor T3 is connected with the first end of the first storage capacitor C1, the first electrode of the third transistor T3 is connected with the second node N2, and the second electrode of the third transistor T3 is connected with the third node N3. The third transistor T3 may be referred to as a drive transistor, and the third transistor T3 determines a magnitude of a drive current according to a potential difference between the gate electrode and the first electrode of the third transistor T3.

In an exemplary implementation, a gate electrode of the fourth transistor T4 is connected with the third scan signal line S3, a first electrode of the fourth transistor T4 is connected with the data signal line DATA, and the second electrode of the fourth transistor T4 is connected with the fifth node N5. When an ON level signal is applied to the third scan signal line S3, the fourth transistor T4 enables a data voltage of the data signal line DATA to be input to the second end of the first storage capacitor C1 and the second end of the second storage capacitor C2.

In an exemplary implementation, a gate electrode of the fifth transistor T5 is connected to the first light emitting signal line EM1, a first electrode of the fifth transistor T5 is connected with the first power supply line VDD, and the second electrode of the fifth transistor T5 is connected with the second node N2. A gate electrode of the sixth transistor T6 is connected with the second light emitting signal line EM2, the first electrode of the sixth transistor T6 is connected with the third node N3, and the second electrode of the sixth transistor T6 is connected with the fourth node N4. When an ON level signal is applied to the first light emitting signal line EM1 and the second light emitting signal line EM2, the fifth transistor T5 and the sixth transistor T6 form a drive current path between the first power supply line VDD and the second power supply line VSS to enable a light emitting device EL to emit light.

In an exemplary implementation, a gate electrode of the seventh transistor T7 is connected with the first scan signal line S1, a first electrode of the seventh transistor T7 is connected with the second initial signal line INIT2, and the second electrode of the seventh transistor T7 is connected with the fourth node N4. When an ON level signal is applied to the first scan signal line S1, the seventh transistor T7 transmits a second initial voltage to a first electrode of the light emitting device EL, which releases charges accumulated in the first electrode of the light emitting device EL and achieves initialization.

In an exemplary implementation, a gate electrode of the eighth transistor T8 is connected with the first scan signal line S1, a first electrode of the eighth transistor T8 is connected with the second reference signal line REF2, and the second electrode of the eighth transistor T8 is connected with the second node N2. When an ON level signal is applied to the first scan signal line S1, the eighth transistor T8 transmits a second reference signal to the second node N2.

In an exemplary implementation, a gate electrode of the ninth transistor T9 is connected with the second scan signal line S2, a first electrode of the ninth transistor T9 is connected with the first reference signal line REF1, and a second electrode of the ninth transistor T9 is connected with the fifth node N5. When an ON level signal is applied to the second scan signal line S2, the ninth transistor T9 transmits a first reference signal to the fifth node N5.

In an exemplary implementation, the light emitting device EL may be an OLED including a first electrode (anode), an organic light emitting layer, and a second electrode (cathode), which are stacked, or may be a QLED including a first electrode (anode), a quantum dot light emitting layer, and a second electrode (cathode), which are stacked. The first electrode of the light emitting device EL is connected with the fourth node N4, the second electrode of the light emitting device EL is connected with the second power supply line VSS, a signal of the second power supply line VSS is a continuously supplied low-level signal, and a signal of the first power supply line VDD is a continuously supplied high-level signal.

In an exemplary implementation, the first transistor T1 to the ninth transistor T9 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the ninth transistor T9 may include a P-type transistor and an N-type transistor.

In an exemplary implementation, for all of the first transistor T1 to the ninth transistor T9, low temperature poly silicon thin film transistors may be used, oxide thin film transistors may be used, or both of low temperature poly silicon thin film transistors and oxide thin film transistors may be used. An active layer of a low temperature poly silicon thin film transistor may be made of Low Temperature Poly Silicon (LTPS), and an active layer of an oxide thin film transistor may be made of an oxide semiconductor (Oxide). The low temperature poly silicon thin film transistor has advantages, such as a high mobility and fast charging, and the oxide thin film transistor has advantages, such a low drain current. The low temperature poly silicon thin film transistor and the oxide thin film transistor are integrated on one display substrate, that is an LTPS and Oxide (LTPO) display substrate, so that advantages of the low temperature poly silicon thin film transistor and the oxide thin film transistor may be utilized, low-frequency drive may be achieved, power consumption may be reduced, and display quality may be improved.

FIG. 5 is a schematic diagram of a planar structure of a display substrate in an exemplary embodiment of the present disclosure, illustrating a structure of a pixel drive circuit in three circuit units (a first circuit unit, a second circuit unit, and a third circuit unit) in the display substrate. In an exemplary implementation, the display substrate may include a drive circuit layer disposed on a substrate, and a light emitting structure layer disposed on a side of the drive circuit layer away from the substrate. The drive circuit layer may include, at least, a plurality of circuit units, the light emitting structure layer may include, at least, a plurality of light emitting units, wherein at least one circuit unit includes a pixel drive circuit, at least one light emitting unit includes a light emitting device that may include, at least, an anode, an organic light emitting layer, and a cathode, and the anode in the light emitting unit is connected with a pixel drive circuit in a corresponding circuit unit. In an exemplary implementation, the circuit units mentioned in the present disclosure refer to regions divided according to pixel drive circuits, and the light emitting units mentioned in the present disclosure refer to regions divided according to light emitting devices. In an exemplary implementation, a position of an orthographic projection of a light emitting unit on the substrate may correspond to a position of an orthographic projection of a circuit unit on the substrate, or a position of an orthographic projection of a light emitting unit on the substrate may not correspond to a position of an orthographic projection of a circuit unit on the substrate.

In an exemplary embodiment, a plurality of circuit units sequentially disposed along a first direction X are referred to as a unit row, and a plurality of circuit units sequentially disposed along a second direction Y are referred to as a unit column. A plurality of unit rows and a plurality of unit columns form an array of circuit units arranged in an array, and the first direction X intersects with the second direction Y.

As shown in FIG. 5, in an exemplary implementation, the drive circuit layer may further include at least one first power supply connection line 68 extending along the first direction X and at least one first power supply line 51 extending along the second direction Y, wherein the at least one first power supply connection line 68 is connected with the pixel drive circuit in the plurality of circuit units, the at least one first power supply line 51 is configured to continuously supply a high-level signal to the pixel drive circuit, the first power supply line 51 extending along the second direction Y and the first power supply connection line 68 extending along the first direction X are connected to each other to form a mesh structure for transmitting a first power supply signal.

In an exemplary implementation, the drive circuit layer may further include at least one second power supply connection line 69 extending along the first direction X and at least one second power supply line 52 extending along the second direction Y, the at least one second power supply connection line 69 is connected with cathodes of a plurality of light emitting units, and the at least one second power supply line 52 is configured to continuously supply a low-level signal to the cathodes, and the at least one second power supply line 52 extending along the second direction Y and the second power supply connection line 69 extending along the first direction X are connected to each other to form a mesh structure for transmitting a second power supply signal.

In an exemplary implementation, the drive circuit layer may further include at least one first reference signal line 91 extending along the first direction X and at least one reference signal connection line 54 extending along the second direction Y, the at least one first reference signal line 91 is connected with a pixel drive circuit in a plurality of circuit units, and the first reference signal line 91 is configured to supply a first reference signal to the pixel drive circuit. The first reference signal line 91 extending along the first direction X and the reference signal connection line 54 extending along the second direction Y are connected to each other to form a mesh structure for transmitting a first reference signal.

In the present disclosure, “A extends along a B direction” means that A may include a main portion and a secondary portion connected with the main portion, the main portion is a line, a line segment, or a strip-shaped body, the main portion extends along the B direction, and a length of the main portion extends along the B direction is greater than a length of the secondary portion extends along another direction.

In an exemplary implementation, in a plane perpendicular to the display substrate, the drive circuit layer may include a semiconductor layer, a first conductive layer, a second conductive layer, a third conductive layer, and a fourth conductive layer that are sequentially disposed on a substrate. The first power supply line 51 and the first power supply connection line 68 may be disposed in different conductive layers, and may be connected through a via. The second power supply line 52 and the second power supply connection line 69 may be disposed in different conductive layers, the second power supply line 52 and the second power supply connection line 69 may be connected through a via, the first reference signal line 91 and the reference signal connection line 54 may be disposed in different conductive layers, and the first reference signal line 91 and the reference signal connection line 54 may be connected through a via.

In an exemplary implementation, the first power supply line 51, the second power supply line 52, and the reference signal connection line 54 may be disposed in a same layer and formed synchronously by a same patterning process, and the first power supply connection line 68, the second power supply connection line 69, and the first reference signal line 91 may be disposed in a same layer and formed synchronously by a same patterning process.

In an exemplary implementation, the first power supply connection line 68, the second power supply connection line 69, and the first reference signal line 91 may be disposed in the third conductive layer, and the first power supply line 51, the second power supply line 52, and the reference signal connection line 54 may be disposed in the fourth conductive layer.

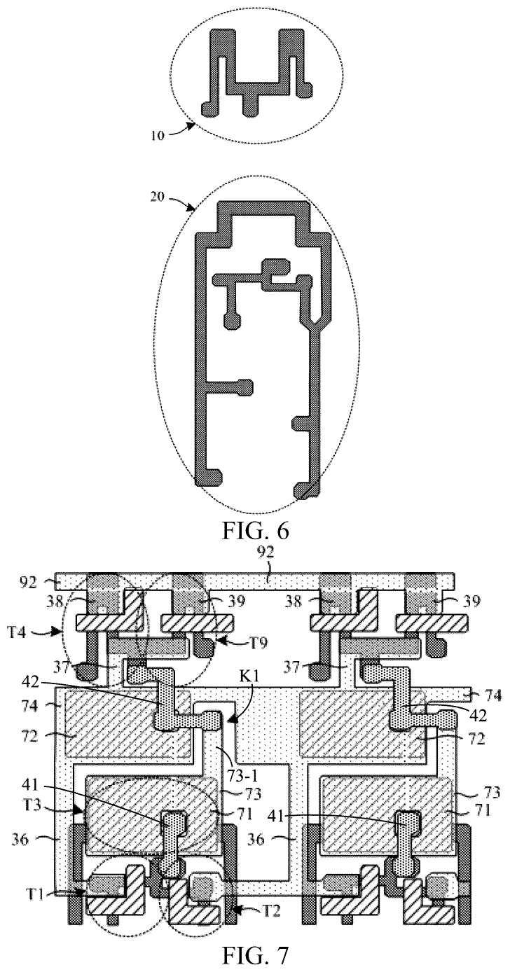

FIG. 6 is a schematic diagram of a structure of the semiconductor layer in FIG. 5, illustrating a structure of a first active pattern and a second active pattern in a circuit unit. As shown in FIG. 6, at least one circuit unit may include a plurality of transistors, and a semiconductor layer of the at least one circuit unit may include, at least, active layers of a plurality of transistors.

In an exemplary implementation, the semiconductor layer of the at least one circuit unit may include, at least, a first active pattern 10 and a second active pattern 20, the first active pattern 10 may include an active layer of at least one transistor, and the second active pattern 20 may include an active layer of at least one transistor.

In an exemplary implementation, in the at least one circuit unit, the first active pattern 10 is spaced from the second active pattern 20. That is, the active layer of the transistor in the first active pattern 10 is not connected to the active layer of the transistor in the second active pattern 20.

In an exemplary implementation, active layers of a plurality of transistors in the at least one circuit unit is spaced from active layers of a plurality of transistors in a circuit unit adjacent in a unit row direction. That is, in the unit row direction, the active layers of the plurality of transistors in the circuit unit is not connected to the active layers of the plurality of transistors in the adjacent circuit unit.

In an exemplary implementation, in the at least one circuit unit, active layers of a plurality of transistors is spaced from active layers of a plurality of transistors in a circuit unit adjacent in a unit column direction. That is, in the unit column direction, the active layers of the plurality of transistors in the circuit unit is not connected to the active layers of the plurality of transistors in the adjacent circuit unit.

In an exemplary implementation, the first active pattern 10 may include active layers of two transistors, and the two transistors are connected to each other to form an integral structure. The second active pattern 20 may include active layers of seven transistors, and the seven transistors are connected to each other to form an integral structure.

In an exemplary implementation, a pixel drive circuit in the at least one circuit unit may include a first transistor T1 and a seventh transistor T7 as initialization transistors, a second transistor T2 as a compensation transistor, a third transistor T3 as a drive transistor, a fourth transistor T4 as a data writing transistor, a fifth transistor T5 and a sixth transistor T6 as light emitting transistors, and an eighth transistor T8 and a ninth transistor T9 as reference transistors. The first active pattern 10 may include an active layer of the fourth transistor T4 and an active layer of the ninth transistor T9, and the second active pattern 20 may include active layers of the first transistor T1 to the third transistor T3 and active layers of the fifth transistor T5 to the eighth transistor T8.

FIG. 7 is a schematic diagram of a regional structure of a first storage capacitor and a second storage capacitor in FIG. 5. As shown in FIGS. 5 and 7, in an exemplary implementation, the first storage capacitor may include, at least, a first plate 71 and a third plate 73, and an orthographic projection of the third plate 73 on the substrate is overlapped, at least partially, with an orthographic projection of the first plate 71 on the substrate. The second storage capacitor may include, at least, a second plate 72 and a fourth plate 74, and an orthographic projection of the fourth plate 74 on the substrate is overlapped, at least partially, with an orthographic projection of the second plate 72 on the substrate.

In an exemplary implementation, the first plate 71 may serve as a gate electrode of the third transistor T3, the second plate 72 is connected with the third plate 73, and the fourth plate 74 is connected with the first power supply line 51.

In an exemplary implementation, a plurality of conductive layers include, at least, a first conductive layer, a second conductive layer, a third conductive layer, and a fourth conductive layer disposed in sequence in a direction away from the substrate. The first plate 71 and the second 72 may be disposed in the first conductive layer, the third and fourth plates 73 and 74 may be disposed in the second conductive layer, the first power supply line 51 may be disposed in the fourth conductive layer, and the second plate 72 may be connected with the third plate 73 through a connection electrode disposed in the third conductive layer.

In an exemplary implementation, a gate electrode of a first transistor T1 is connected with a fourth scan signal line 64, a first electrode of the first transistor T1 is connected with a first initial signal line 81, and a second electrode of the first transistor T1 is connected with a first electrode of the second transistor T2, and the first plate 71 of the first storage capacitor, respectively. A gate electrode of the second transistor T2 is connected with a fifth scan signal line 65, and a second electrode of the second transistor T2 is connected with a second electrode of the third transistor T3, and a first electrode of the sixth transistor T6, respectively. A gate electrode of the third transistor T3 serves as the first plate 71 of the first storage capacitor, and a first electrode of the third transistor T3 is connected with a second electrode of the fifth transistor T5, and a second electrode of the eighth transistor T8, respectively. A gate electrode of the fourth transistor T4 is connected with a third scan signal line 63, a first electrode of the fourth transistor T4 is connected with a data signal line 53, and a second electrode of the fourth transistor T4 is connected with a second electrode of the ninth transistor T9, the third plate 73 of the first storage capacitor, and the second plate 72 of the second storage capacitor, respectively. A gate electrode of the fifth transistor T5 is connected with a first light emitting signal line 31, and a first electrode of the fifth transistor T5 is connected with the first power supply line 51. A gate electrode of the sixth transistor T6 is connected with a second light emitting signal line 32, and a second electrode of the sixth transistor T6 is connected with a second electrode of the seventh transistor T7. A gate electrode of the seventh transistor T7 is connected with a first scan signal line 61, and a first electrode of the seventh transistor T7 is connected with a second initial signal line 82. A gate electrode of the eighth transistor T8 is connected with the first scan signal line 61, and a first electrode of the eighth transistor T8 is connected with the second reference signal line 92. A gate electrode of the ninth transistor T9 is connected with a second scan signal line 62, and a first electrode of the ninth transistor T9 is connected to the first reference signal line 91.

In an exemplary implementation, the second scan signal line 62 and the fifth scan signal line 65 transmit a same scan signal.

In an exemplary implementation, shapes of the first scan signal line 61, the second scan signal line 62, the third scan signal line 63, the fourth scan signal line 64, the fifth scan signal line 65, the first light emitting signal line 31, the second light emitting signal line 32, the first initial signal line 81, the second initial signal line 82, the first reference signal line 91, and the second reference signal line 92 may be line shapes in which a main portion extends along the first direction X, and shapes of the first power supply line 51 and the data signal line 53 may be line shapes in which a main portion extends along the second direction Y.

In an exemplary implementation, the at least one circuit unit may further include an anode connection electrode 55 connected. On one hand, the anode connection electrode 55 connected to the second electrode of the sixth transistor T6 and the second electrode of the seventh transistor T7, respectively. On the other hand, the anode connection electrode 55 is connected to the anode of the light emitting unit.

In an exemplary implementation, the drive circuit layer may further include a repair line 33 whose shape may be a line shape in which the main portion extends along the first direction X, an orthographic projection of the repair line 33 on the substrate is overlapped, at least partially, with an orthographic projection of the anode connection electrode 55 on the substrate, and the repair line 33 is configured to enable a signal to be input, through the repair line 33, to an anode of a sub-pixel where a bright spot defect occurs when the bright spot defect occurs on the display substrate, so as to repair a dark spot.

In an exemplary implementation, the at least one circuit unit may further include a first connection electrode 41 connected to the second electrode of the first transistor T1, the first electrode of the second transistor T2, and the first plate 71 of the first storage capacitor, respectively, and the first connection electrode 41 may serve as a first node of the pixel drive circuit.

In an exemplary implementation, the at least one circuit unit may further include a power supply shield block 51-1 connected with the first power supply line 51, an orthographic projection of the power supply shield block 51-1 on the substrate is overlapped, at least partially, with an orthographic projection of the first connection electrode 41 on the substrate, so as to shield an influence of other signals in the pixel drive circuit on the first node.

In an exemplary implementation, the at least one circuit unit may further include a second connection electrode 42 connected with the second electrode of the fourth transistor T4, the second electrode of the ninth transistor T9, the third plate 73 of the first storage capacitor and the second plate 72 of the second storage capacitor, respectively, and the second connection electrode 42 may serve as a fifth node N5 in the pixel drive circuit.

In an exemplary implementation, an orthographic projection of the first power supply line 51 on the substrate is overlapped, at least partially, with an orthographic projection of the second connection electrode 42 on the substrate, so as to shield an influence of other signals in the pixel drive circuit on the fifth node.

In an exemplary implementation, the at least one circuit unit may further include a first shield electrode 36 connected with the fourth plate 74, an orthographic projection of the first shield electrode 36 on the substrate is overlapped, at least partially, with an orthographic projection of a semiconductor layer between two gate electrodes of the first transistor T1 on the substrate, and the orthographic projection of the first shield electrode 36 on the substrate is overlapped, at least partially, with an orthographic projection of a semiconductor layer between two gate electrodes of the second transistor T2 on the substrate. In an exemplary implementation, the first shield electrode 36 is configured to shield an influence of data voltage jump on the first transistor T1 and the second transistor T2, so as to avoid the data voltage jump affecting a normal operation of the pixel drive circuit, and to improve the display effect.

In an exemplary implementation, the at least one circuit unit may further include a second shield electrode 37 connected with the fourth plate 74, and an orthographic projection of the second shield electrode 37 on the substrate is overlapped, at least partially, with orthographic projections of the second electrode of the fourth transistor T4 and the second electrode of the ninth transistor T9 on the substrate. In an exemplary implementation, the second shield electrode 37 is configured to shield an influence of data voltage jump on the fifth node, so as to avoid the data voltage jump affecting the normal operation of the pixel drive circuit, and to improve the display effect.

In an exemplary implementation, the fourth plate 74, the first shield electrode 36 and the second shield electrode 37 may be connected to each other to form an integral structure.

In an exemplary implementation, the at least one circuit unit may further include an additional capacitor of the second storage capacitor, wherein a lower plate of the additional capacitor is disposed in the semiconductor layer, an upper plate of the additional capacitor is disposed in the second conductive layer, an orthographic projection of the upper plate on the substrate is overlapped, at least partially, with an orthographic projection of the lower plate on the substrate, the lower plate is connected with the second plate, and the upper plate is connected with the fourth plate.

In an exemplary implementation, the lower plate of the additional capacitor is a second region of the active layer of the fourth transistor T4 (that is, a second region of the active layer of the ninth transistor T9), and the upper plate of the additional capacitor is the second shield electrode 37. Since the second region of the active layer of the fourth transistor T4 is connected with the second plate 72 through the second connection electrode 42, and the second shield electrode 37 and the fourth plate 74 are connected to each other to form an integral structure, the additional capacitor of the second storage capacitor is formed. The additional capacitor is connected in parallel with the second storage capacitor, which may effectively increase a total capacity of the second storage capacitor, improving an operation performance of the pixel drive circuit and improving the display effect.

In an exemplary implementation, the at least one circuit unit may further include a third shield electrode 38 connected with the second reference signal line 92, wherein an orthographic projection of the third shield electrode 38 on the substrate is overlapped, at least partially, with an orthographic projection of a semiconductor layer between two gate electrodes of the fourth transistor T4 on the substrate. In an exemplary implementation, the third shield electrode 38 is configured to shield an influence of data voltage jump on the fourth transistor T4, so as to avoid the data voltage jump affecting the normal operation of the pixel drive circuit, and to improve the display effect.

In an exemplary implementation, the at least one circuit unit may further include a fourth shield electrode 39 connected with the second reference signal line 92, wherein an orthographic projection of the fourth shield electrode 39 on the substrate is overlapped, at least partially, with an orthographic projection of a semiconductor layer between two gate electrodes of the ninth transistor T9 on the substrate. In an exemplary implementation, the fourth shield electrode 39 is configured to shield an influence of data voltage jump on the ninth transistor T9, so as to avoid the data voltage jump affecting the normal operation of the pixel drive circuit, and to improve the display effect.

In an exemplary implementation, the third shield electrode 38, the fourth shield electrode 39 and the second reference signal line 92 may be connected to each other to form an integral structure.

In an exemplary implementation, a first plate connection line 73-1 is provided on a side of the third plate 73 of the at least one circuit unit close to the fourth plate 74, a first groove K1 recessed toward a direction away from the third plate 73 is provided on a side of the fourth plate 74 close to the third plate 73, wherein the first plate connection line 73-1 is disposed in the first groove K1, and an end of the first plate connection line 73-1 away from the third plate 73 is connected with the second connection electrode 42 through a via.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire manufacturing process, the “thin film” may also be referred to as a “layer”. If the “thin film” needs to be processed through the patterning process in the entire manufacturing process, the “thin film” is referred to as a “thin film” before the patterning process is performed and is referred to as a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film is a dimension of the film in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, three circuit units (a first circuit unit, a second circuit unit, and a third circuit unit) in an n-th unit row are taken as an example, the manufacturing process of a display substrate in the embodiment may include the following acts.

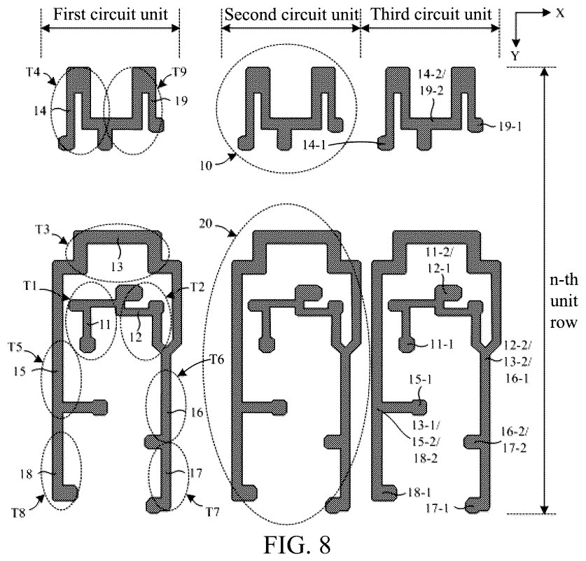

(11) A pattern of a semiconductor layer is formed. In an exemplary implementation, forming the pattern of the semiconductor layer may include: a first insulation thin film and a semiconductor thin film are deposited sequentially on a substrate, and the semiconductor thin film is patterned through a patterning process to form a first insulation layer that covers the substrate and the semiconductor layer disposed on the first insulation layer, as shown in FIG. 8.

In an exemplary implementation, a semiconductor layer of each circuit unit in the display substrate may include, at least, a first active layer 11 of a first transistor T1, a second active layer 12 of a second transistor T2, a third active layer 13 of a third transistor T3, a fourth active layer 14 of a fourth transistor T4, a fifth active layer 15 of a fifth transistor T5, a sixth active layer 16 of a sixth transistor T6, a seventh active layer 17 of a seventh transistor T7, an eighth active layer 18 of an eighth transistor T8 and a ninth active layer 19 of a ninth transistor T9, and the first to third active layers 11 to 13 and the fifth to eighth active layers 15 to 18 may be connected to each other to form an integral structure, and the fourth and ninth active layers 14 and 19 may be connected to each other to form an integral structure.

In an exemplary implementation, a fourth active layer 14 and a ninth active layer 19 in an n-th unit row may be located on a side of the third active layer 13 close to an (n−1)-th unit row. That is, the fourth active layer 14 and the ninth active layer 19 may be located on a side opposite to a second direction Y of the third active layer 13 in the circuit unit. A first active layer 11, the second active layer 12, the fifth to eighth active layers 15 to 18 in the n-th unit row may be located on a side of the third active layer 13 close to an (n+1)-th unit row. That is, the first active layer 11, the second active layer 12, the fifth to eighth active layers 15 to 18 may be located on a side of the third active layer 13 of the circuit unit in the second direction Y.

In an exemplary implementation, the first active layer 11 may be located on a side of the third active layer 13 of the circuit unit in the second direction Y, the fifth active layer 15 may be located on a side of the first active layer 11 of the circuit unit in the second direction Y, and the eighth active layer 18 may be located on a side of the fifth active layer 15 of the circuit unit in the second direction Y. The second active layer 12 may be located on a side of the third active layer 13 of the circuit unit in the second direction Y, the sixth active layer 16 may be located on a side of the second active layer 12 of the circuit unit in the second direction Y, and the seventh active layer 17 may be located on a side of the sixth active layer 16 of the circuit unit in the second direction Y.

In an exemplary implementation, the first active layer 11, the fourth active layer 14, the fifth active layer 15 and the eighth active layer 18 may be located on a side of the circuit unit in a first direction X (e.g. an opposite side in the first direction X), and the second active layer 12, the sixth active layer 16, the seventh active layer 17 and the ninth active layer 19 may be located on another side of the circuit unit in the first direction X (e.g. a side in the first direction X).

In an exemplary implementation, shapes of the first and second active layers 11 and 12 may be “L” shaped, a shape of the third active layer 13 may be “C” shaped, shapes of the fourth and ninth active layers 14 and 19 may be “n” shaped, and shapes of the fifth, sixth, seventh and eighth active layers 15, 16, 17 and 18 may be “I” shaped.

In an exemplary implementation, an active layer of each transistor may include a first region, a second region, and a channel region located between the first region and the second region. In an exemplary implementation, a second region 11-2 of the first active layer and a first region 12-1 of the second active layer may be connected to each other, such that the second region 11-2 of the first active layer may serve as the first region 12-1 of the second active layer. A first region 13-1 of the third active layer, a second region 15-2 of the fifth active layer, and a second region 18-2 of the eighth active layer may be connected to each other, such that the first region 13-1 of the third active layer may serve as the second region 15-2 of the fifth active layer and the second region 18-2 of the eighth active layer at the same time, forming a second node N2 of the pixel drive circuit. A second region 12-2 of the second active layer, a second region 13-2 of the third active layer and a first region 16-1 of the sixth active layer may be connected to each other, such that the second region 13-2 of the third active layer may serve as the second region 12-2 of the second active layer and the first region 16-1 of the sixth active layer at the same time, forming a third node N3 of the pixel drive circuit. A second region 14-2 of the fourth active layer and a second region 19-2 of the ninth active layer may be connected to each other, such that the second region 14-2 of the fourth active layer may serve as the second region 19-2 of the ninth active layer. A second region 16-2 of the sixth active layer and a second region 17-2 of the seventh active layer may be connected to each other, and the second region 16-2 of the sixth active layer may serve as the second region 17-2 of the seventh active layer, forming a fourth node N4 of the pixel drive circuit. A first region 11-1 of the first active layer, a first region 14-1 of the fourth active layer, a first region 15-1 of the fifth active layer, a first region 17-1 of the seventh active layer, a first region 18-1 of the eighth active layer, and a first region 19-1 of the ninth active layer may be provided separately, the first region 14-1 of the fourth active layer may be located on a side of a channel region of the fourth active layer close to the third active layer 13, and the first region 19-1 of the ninth active layer may be located on a side of a channel region of the ninth active layer close to the third active layer 13.

In an exemplary implementation, the semiconductor layer of the at least one circuit unit may include, at least, a first active pattern 10 and a second active pattern 20, the first active pattern 10 may include the active layer of the fourth transistor T4 and the active layer of the ninth transistor T9, and the second active pattern 20 may include the active layers of the first transistor T1 to the third transistor T3 and the active layers of the fifth transistor T5 to the eighth transistor T8.

In an exemplary implementation, in the at least one circuit unit, the first active pattern 10 is spaced from the second active pattern 20. That is, the active layer of the transistor in the first active pattern 10 is not connected to the active layer of the transistor in the second active pattern 20.

In an exemplary implementation, in at least one unit row, semiconductor layers in circuit units adjacent in the first direction X are spaced from each other. That is, a semiconductor layer of a first circuit unit in the n-th unit row is not connected to a semiconductor layer of a second circuit unit in the n-th unit row, and the semiconductor layer of the second circuit unit in the n-th unit row is not connected to a semiconductor layer of a third circuit unit in the n-th unit row.

In an exemplary implementation, in at least one unit column, semiconductor layers in circuit units adjacent in the second direction Y are spaced from each other. That is, a semiconductor layer of a first circuit unit in the (n−1)-th unit row is not connected to a semiconductor layer of a first circuit unit in the n-th unit row, and the semiconductor layer of the first circuit unit in the n-th unit row is not connected to a semiconductor layer of a first circuit unit in the (n+1)-th unit row.

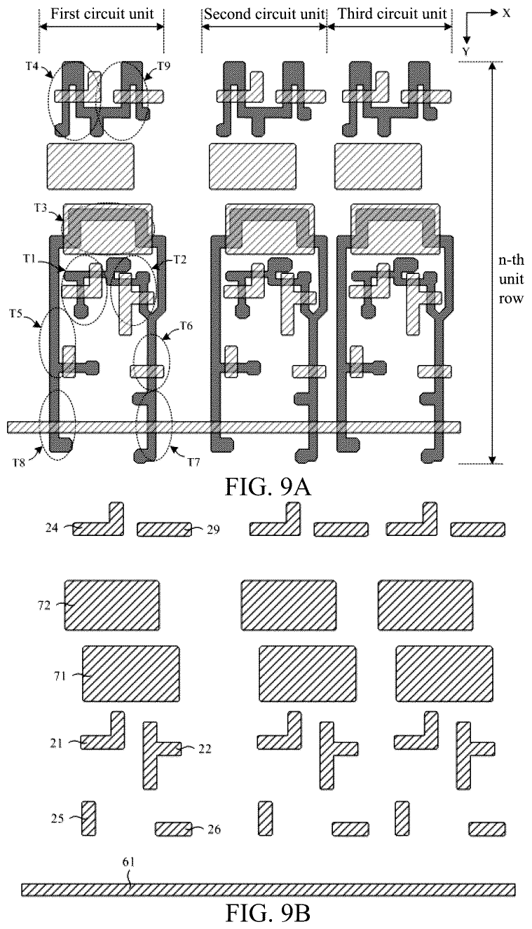

(12) A pattern of a first conductive layer is formed. In an exemplary implementation, forming the pattern of the first conductive layer may include: a second insulation thin film and a first conductive thin film are deposited sequentially on the substrate on which the aforementioned patterns are formed, and the first conductive thin film is patterned through a patterning process to form a second insulation layer that covers the pattern of the semiconductor layer, and a pattern of a first conductive layer disposed on the second insulation layer, as shown in FIG. 9A and FIG. 9B, wherein FIG. 9B is a schematic diagram of the first conductive layer in FIG. 9A. In an exemplary implementation, the first conductive layer may be referred to as a first gate metal (GATE1) layer.

In an exemplary implementation, a pattern of a first conductive layer of each circuit unit in the display substrate includes, at least, a first gate electrode 21, a second gate electrode 22, a fourth gate electrode 24, a fifth gate electrode 25, a sixth gate electrode 26, a ninth gate electrode 29, a first scan signal line 61, a first plate 71 of a first storage capacitor, and a second plate 72 of a second storage capacitor.

In an exemplary implementation, a shape of the first gate electrode 21 may be “L” shaped, the first gate electrode 21 may be located on a side of the first plate 71 in the second direction Y, and a region where the first gate electrode 21 is overlapped with the first active layer may serve as a gate electrode of the first transistor T1 being of a double gate structure.

In an exemplary implementation, a shape of the second gate electrode 22 may be “T” shaped, the second gate electrode 22 may be located on the side of the first plate 71 in the second direction Y, and a region where the second gate electrode 22 is overlapped with the second active layer may serve as a gate electrode of the second transistor T2 being of a double gate structure.

In an exemplary implementation, a shape of the fourth gate electrode 24 may be “L” shaped, the fourth gate electrode 24 may be located on a side opposite to the second plate 72 in the second direction Y, and a region where the fourth gate electrode 24 is overlapped with the fourth active layer may serve as a gate electrode of the fourth transistor T4 being of a double-gate structure.

In an exemplary embodiment, a shape of the fifth gate electrode 25 may be a shape of strip extending along the second direction Y, the fifth gate electrode 25 may be located on a side of the first gate electrode 21 in the second direction Y, and a region where the fifth gate electrode 25 is overlapped with the fifth active layer may serve as a gate electrode of the fifth transistor T5.

In an exemplary implementation, a shape of the sixth gate electrode 26 may be a shape of strip extending along the first direction X, the sixth gate electrode 26 may be located on a side of the second gate electrode 22 in the second direction Y, and a region where the sixth gate electrode 26 is overlapped with the sixth active layer may serve as a gate electrode of the sixth transistor T6.

In an exemplary implementation, a shape of the ninth gate electrode 29 may be a shape of strip extending along the first direction X, the ninth gate electrode 29 may be located on a side opposite to the second plate 72 in the second direction Y, and a region where the ninth gate electrode 29 is overlapped with the ninth active layer may serve as a gate electrode of the ninth transistor T9 being of a double gate structure.

In an exemplary implementation, a shape of the first scan signal line 61 may be a shape of line in which a main portion extends along the first direction X, the first scan signal line 61 may be located on a side of the fifth gate electrode 25 and the sixth gate electrode 26 in the second direction Y, a region where the first scan signal line 61 is overlapped with the seventh active layer may serve as a gate electrode of the seventh transistor T7, and a region where the first scan signal line 61 is overlapped with the eighth active layer may serve as a gate electrode of the eighth transistor T8.

In an exemplary implementation, a shape of the first plate 71 of the first storage capacitor may be a shape of rectangle in which corners of the rectangle may be chamfered, an orthographic projection of the first plate 71 on the substrate is overlapped, at least partially, with an orthographic projection of the third active layer of the third transistor T3 on the substrate, and the first plate 71 may serve as a lower plate of the first storage capacitor and a gate electrode of the third transistor T3 at the same time.

In an exemplary implementation, a shape of the second plate 72 of the second storage capacitor may be a shape of rectangle, in which corners of the rectangle may be chamfered, and the second plate 72 may be located on a side opposite to the first plate 71 in the second direction Y, and on a side of the fourth gate electrode 24 and the ninth gate electrode 29 in the second direction Y. That is, in the second direction Y, the second plate 72 is located between the first plate 71 and the fourth gate electrode 24 (the ninth gate electrode 29), and an orthographic projection of the second plate 72 on the substrate is not overlapped with an orthographic projection of the semiconductor layer on the substrate. In an exemplary implementation, the second plate 72 may serve as a lower plate of the second storage capacitor.

In an exemplary implementation, an area of the orthographic projection of the first plate 71 on the substrate may be the same as or different from an area of the orthographic projection of the second plate 72 on the substrate. For example, the area of the orthographic projection of the second plate 72 on the substrate may be larger than the area of the orthographic projection of the first plate 71 on the substrate.

In an exemplary implementation, after the pattern of the first conductive layer is formed, a conductive processing may be performed on the semiconductor layer by using the first conductive layer as a shield, a semiconductor layer in a region shielded by the first conductive layer forms channel regions of the first transistor T1 to the ninth transistor T9, and a semiconductor layer in a region not shielded by the first conductive layer is made to be conductive. That is, all of the first regions and the second regions of the first active layer to the ninth active layer are made to be conductive.

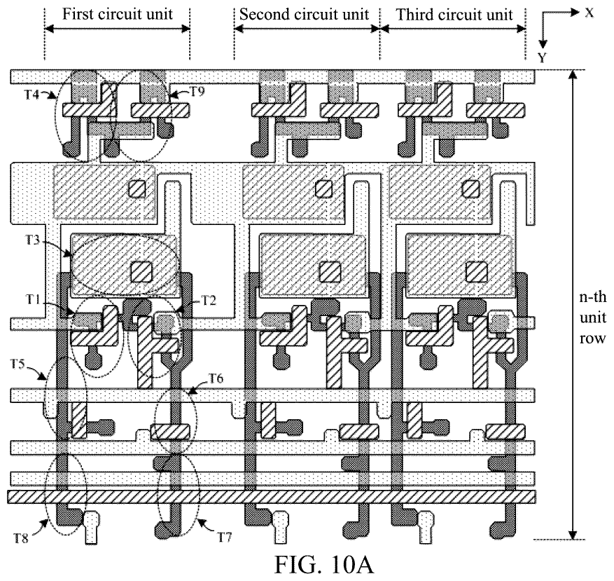

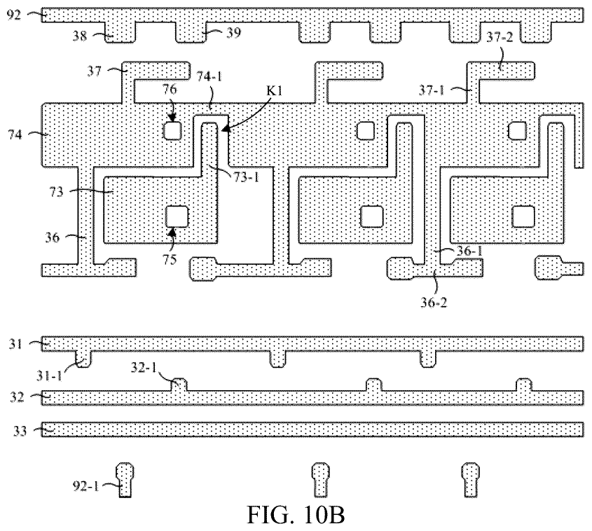

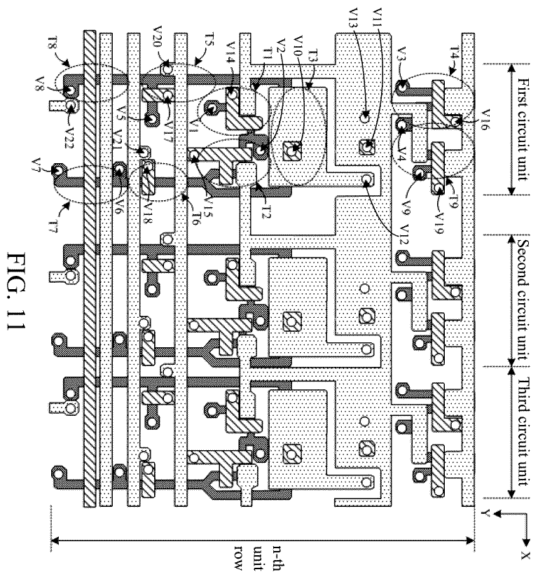

(13) A pattern of a second conductive layer is formed. In an exemplary implementation, forming the pattern of the second conductive layer may include: a third insulation thin film and a second conductive thin film are sequentially deposited on the substrate on which the aforementioned patterns are formed, and the second conductive thin film is patterned through a patterning process to form a third insulation layer that covers the first conductive layer and a pattern of a second conductive layer disposed on the third insulation layer, as shown in FIG. 10A and FIG. 10B, wherein FIG. 10B is a schematic diagram of the second conductive layer in FIG. 10A. In an exemplary implementation, the second conductive layer may be referred to as a second gate metal (GATE2) layer.

In an exemplary implementation, a pattern of a second conductive layer of each circuit unit in the display substrate includes, at least, a first light emitting signal line 31, a second light emitting signal line 32, a repair line 33, a first shield electrode 36, a second shield electrode 37, a third shield electrode 38, a fourth shield electrode 39, a third plate 73 of a first storage capacitor, a fourth plate 74 of a second storage capacitor, and a second reference signal line 92.

In an exemplary implementation, each of shapes of the first light emitting signal line 31, the second light emitting signal line 32, the repair line 33, and the second reference signal line 92 may be a shape of line in which a main portion extends along the first direction X, the first light emitting signal line 31, the second light emitting signal line 32, and the repair line 33 may be located between the first gate electrode 21 and the first scan signal line 61, and the second reference signal line 92 may be located on a side opposite to the fourth gate electrode 24 in the second direction Y.

In an exemplary implementation, the first light emitting signal line 31 may be located on a side of the first gate electrode 21 of the circuit unit in the second direction Y, the second light emitting signal line 32 may be located on a side of the first light emitting signal line 31 of the circuit unit in the second direction Y, and the repair line 33 may be located on a side of the second light emitting signal line 32 of the circuit unit in the second direction Y. That is, the second light emitting signal line 32 may be located between the first light emitting signal line 31 and the repair line 33.

In an exemplary implementation, a first light emitting connection block 31-1 is provided on a side of the first light emitting signal line 31 close to the second light emitting signal line 32, the first light emitting connection block 31-1 may be provided in each circuit unit, a first end of the first light emitting connection block 31-1 is connected with the first light emitting signal line 31, a second end of the first light emitting connection block 31-1 extends in a direction toward the second light emitting signal line 32, and the first light emitting connection block 31-1 is configured to connect with the fifth gate electrode 25 through the seventh connection electrode formed later. In an exemplary implementation, the first light emitting signal line 31 and a plurality of first light emitting connection blocks 31-1 may be connected to each other to form an integral structure.

In an exemplary implementation, a second light emitting connection block 32-1 is provided on a side of the second light emitting signal line 32 close to the first light emitting signal line 31. The second light emitting connection block 32-1 may be disposed in each circuit unit, a first end of the second light emitting connection block 32-1 is connected with the second light emitting signal line 32, a second end of the second light emitting connection block 32-1 extends in a direction toward the first light emitting signal line 31, and the second light emitting connection block 32-1 is configured to connect with the sixth gate electrode 26 through an eighth connection electrode formed later. In an exemplary implementation, the second light emitting signal line 32 and a plurality of light emitting connection blocks 32-1 may be connected to each other to form an integral structure.

In an exemplary implementation, a second reference connection block 92-1 is provided on a side of the second reference signal line 92 in the n-th unit row away from the second plate 72 in the n-th unit row. The second reference connection block 92-1 may be disposed in each circuit unit, a first end of the second reference connection block 92-1 is connected with the second reference signal line 92, and a second end of the second reference connection block 92-1 extends in a direction away from the second plate 72, that is, in a direction toward an (n−1)-th unit row. In an exemplary implementation, the second reference connection block 92-1 of the second reference signal line 92 in the n-th unit row is configured to connect to a first region of an eighth active layer in the (n−1)-th unit row through a sixth connection electrode formed later, so as to provide the second reference signal to a first electrode of the eighth transistor T8 in the (n−1)-th unit row. In an exemplary implementation, the second reference signal line 92 and a plurality of second reference connection blocks 92-1 may be connected to each other to form an integral structure.

In an exemplary implementation, a contour shape of the third plate 73 of the first storage capacitor may be a shape of rectangle in which corners of the rectangle may be chamfered, the third plate 73 of the first storage capacitor may be located between the first light emitting signal line 31 and the second reference signal line 92 in this circuit unit, an orthographic projection of the third plate 73 on the substrate is overlapped, at least partially, with an orthographic projection of the first plate 71 on the substrate, the third plate 73 may serve as an upper plate of the first storage capacitor (a second end of the first storage capacitor C1), and the first plate 71 and the third plate 73 form the first storage capacitor C1 of the pixel drive circuit.

In an exemplary implementation, a contour shape of the fourth plate 74 of the second storage capacitor may be a shape of rectangle in which corners of the rectangle may be chamfered. The fourth plate 74 may be located between the second reference signal line 73 and the third plate 92 of the circuit unit, an orthographic projection of the fourth plate 74 on the substrate is overlapped, at least partially, with the orthographic projection of the second plate 72 on the substrate. The fourth plate 74 may serve as an upper plate of the second storage capacitor (a first end of the second storage capacitor C2), and the second plate 72 and the fourth plate 74 form the second storage capacitor C2 of the pixel drive circuit.

In an exemplary implementation, an area of the orthographic projection of the third plate 73 on the substrate may be the same as or different from an area of the orthographic projection of the fourth plate 74 on the substrate. For example, the area of the orthographic projection of the fourth plate 74 on the substrate may be larger than the area of the orthographic projection of the third plate 73 on the substrate.

In an exemplary implementation, a first plate connection line 73-1 is provided on a side of the third plate 73 close to the fourth plate 74, a first end of the first plate connection line 73-1 is connected with the third plate 73, a second end of the first plate connection line 73-1 extends in the direction toward the second reference signal line 92, and the first plate connection line 73-1 is configured to connect to the second region of the fourth active layer (that is, the second region of the ninth active layer) through a second connection electrode formed later, so that the second electrode of the fourth transistor T4, the second electrode of the ninth transistor T9 and the third plate 73 are at a same potential.

In an exemplary implementation, a second plate connection line 74-1 is provided on a side of the fourth plate 74 in the first direction X or on an opposite side in the first direction X. A first end of the second plate connection line 74-1 is connected with the fourth plate 74 of this circuit unit, and a second end of the second plate connection line 74-1 extends along the first direction X or extends reversely in the first direction X to connect with a fourth plate 74 of an adjacent circuit unit, such that fourth plates 74 of adjacent circuit units in a unit row are connected to each other. In an exemplary implementation, a plurality of fourth plates 74 and a plurality of second plate connection lines 74-1 may be connected to each other to form an integral structure. Since the plurality of fourth plates 74 are connected with a first power supply line formed subsequently, the plurality of fourth plates 74 in a circuit unit integral structure may be reused as a transverse power supply line extending along the first direction X, which not only ensures that the plurality of fourth plates in a unit row are at a same potential, but also reduces a voltage drop of a first power supply signal, which is beneficial to improving uniformity of the panel, avoiding poor display of the display substrate, and ensuring the display effect of the display substrate.

In an exemplary embodiment, a first groove K1 may be formed at edges of two fourth plates 74 adjacent to each other in the first direction X, and at an edge of the second plate connection line 74-1. The first groove K1 is configured to accommodate the first plate connection line 73-1, the first plate connection line 73-1 on the third plate 73 extends in a direction toward the second reference signal line 92 in the first groove K1, so that a subsequently formed twelfth via may be moved upward as much as possible, and as close to the second region of the fourth active layer (that is, the second region of the ninth active layer) as possible. The twelfth via is configured to connect the subsequently formed second connection electrode with the first plate connection line 73-1 through this via, and the second connection electrode is simultaneously connected with the second region of the fourth active layer (that is, the second region of the ninth active layer) through this via, so that the second electrode of the fourth transistor T4, the second electrode of the ninth transistor T9, and the third plate 73 are at a same potential.

In an exemplary implementation, a third plate 73 of each circuit unit is provided with a first opening 75. The first opening 75 may be located in a middle of the third plate 73, and the first opening 75 may be rectangular, such that the third plate 73 forms an annular structure. The first opening 75 exposes a third insulation layer covering the first plate 71, and an orthographic projection of the first plate 71 on the substrate contains an orthographic projection of the first opening 75 on the substrate. In an exemplary implementation, the first opening 75 is configured to accommodate a tenth via formed later, and the tenth via is located within the first opening 75 and exposes the first plate 71, so that a first connection electrode formed later is connected with the first plate 71.

In an exemplary implementation, a fourth plate 74 of each circuit unit is provided with a second opening 76. The second opening 76 may be located in a middle of the fourth plate 74, and the second opening 76 may be rectangular, such that the fourth plate 74 forms an annular structure. The second opening 76 exposes a third insulation layer covering the second plate 72, and an orthographic projection of the second plate 72 on the substrate contains an orthographic projection of the second opening 76 on the substrate. In an exemplary implementation, the second opening 76 is configured to accommodate an eleventh via formed later, and the eleventh via is located within the second opening 76 and exposes the second plate 72, so that the second connection electrode formed later is connected with the second plate 72.

In an exemplary implementation, a shape of the first shield electrode 36 may be “T” shaped, the first shield electrode 36 may be located on a side of the fourth plate 74 close to the first light emitting signal line 31, and may be disposed in each circuit unit. The “T” shaped first shield electrode 36 may include a first extension segment 36-1 and a first shield segment 36-2, wherein a first end of the first extension segment 36-1 is connected with the fourth plate 74, and a second end of the first extension segment 36-1 is connected with the first shield segment 36-2 after extending toward the light emitting signal line 31. A shape of the first shield segment 36-2 may be a shape of strip extending along the first direction X. For a first shield end of the first shield segment 36-2 located on a side of the first extension segment 36-1 in first direction X, and a second shield end of the first shield segment 36-2 located on an opposite side of the first extension segment 36-1 in the first direction X, an orthographic projection of the first shield end on the substrate is overlapped, at least partially, with an orthographic projection of a first active layer between the two gate electrodes of the first transistor T1 in the circuit unit on the substrate, and an orthographic projection of the second shield end on the substrate is overlapped, at least partially, with an orthographic projection of a second active layer between two gate electrodes of a second transistor T2 in an adjacent circuit unit on the substrate. In an exemplary implementation, the first shield electrode 36 is configured to shield an influence of data voltage jump on the first transistor T1 and the second transistor T2, so as to avoid the data voltage jump affecting a normal operation of the pixel drive circuit, and to improve the display effect.

In an exemplary implementation, a shape of the second shield electrode 37 may be “L” shaped, the second shield electrode 37 may be located on a side of the fourth plate 74 close to the second reference signal line 92, and may be disposed in each circuit unit. The “L” shaped second shield electrode 37 may include a second extension segment 37-1 and a second shield segment 37-2, wherein a first end of the second extension segment 37-1 is connected with the fourth plate 74, and a second end of the second extension segment 37-1 is connected with the second shield segment 37-2 after extending toward the second reference signal line 92. The shape of the second shield segment 37-2 may be a shape of strip extending along the first direction X, and an orthographic projection of the second shield segment 37-2 on the substrate is overlapped, at least partially, with orthographic projections of the second region of the fourth active layer and the second region of the ninth active layer on the substrate in this circuit unit. In an exemplary implementation, the second shield electrode 37 is configured to shield an influence of data voltage jump on the fifth node N5, so as to avoid the data voltage jump affecting the normal operation of the pixel drive circuit, and to improve the display effect.

In an exemplary implementation, the first shield electrode 36, the second shield electrode 37 and the fourth plate 74 may be connected to each other to form an integral structure.

In an exemplary implementation, since the second region of the fourth active layer (the second region of the ninth active layer) is a conductive layer which is made to be conductive, and the second shield electrode 37 of the second conductive layer is also a conductive layer, the second region of the fourth active layer (the second region of the ninth active layer) and the second shield electrode 37 may form an additional capacitor of the second storage capacitor. The lower plate of the additional capacitor is arranged on the semiconductor layer and is connected to the second plate 72 through the second connection electrode formed subsequently. The upper plate (the second shield electrode 37) of the additional capacitor is arranged on the second conductive layer, the upper plate and the fourth plate 74 are connected to each other and in an integral structure. Thus an additional capacitance of the second storage capacitor is formed, and the additional capacitance is connected in parallel with the second storage capacitor. In the present disclosure, by forming the additional capacitor of the second storage capacitor, a total capacity of the second storage capacitor can be effectively increased, which improves an operating performance of the pixel drive circuit, and improves the display effect.

In an exemplary implementation, the third shield electrode 38 and the fourth shield electrode 39 may be rectangular, may be located on a side of the second reference signal line 92 close to the fourth plate 74, and may be disposed in each circuit unit. First ends of the third shield electrode 38 and the fourth shield electrode 39 are connected with the second reference signal line 92, and second ends of the third shield electrode 38 and the fourth shield electrode 39 extend in a direction toward the fourth plate 74. An orthographic projection of the third shield electrode 38 on the substrate is overlapped, at least partially, with an orthographic projection of the fourth active layer between the two gate electrodes of the fourth transistor T4 in this circuit unit on the substrate, and an orthographic projection of the fourth shield electrode 39 on the substrate is overlapped, at least partially, with an orthographic projection of the ninth active layer between the two gate electrodes of the ninth transistor T9 in this circuit unit on the substrate. In an exemplary implementation, the third shield electrode 38 is configured to shield an influence of the data voltage jump on the fourth transistor T4, and the fourth shield electrode 39 is configured to shield an influence of the data voltage jump on the ninth transistor T9, so as to avoid the data voltage jump affecting the normal operation of the pixel drive circuit and improve the display effect.

In an exemplary implementation, the third shield electrode 38, the fourth shield electrode 39, and the second reference signal line 92 may be connected to each other to form an integral structure.

In an exemplary implementation, the repair line 33 serves as a pre-set repair signal line, so that when a bright spot defect occurs in the display substrate, a signal is inputted to an anode of a sub-pixel where the bright spot defect occurs through the repair line 33 to repair the bright spot defect to a dark spot.

(14) A pattern of a fourth insulation layer is formed. In an exemplary implementation, forming the pattern of the fourth insulation layer may include: a fourth insulation thin film is deposited on the substrate on which the aforementioned patterns are formed, and the fourth insulation thin film is patterned through a patterning process, to form a fourth insulation layer that covers the second conductive layer, wherein a plurality of vias are disposed on each circuit unit, as shown in FIG. 11.

In an exemplary implementation, a plurality of vias of each circuit unit in the display substrate at least includes a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, and a twenty-second via V22.

In an exemplary implementation, an orthographic projection of the first via V1 on the substrate is within a range of an orthographic projection of the first region of the first active layer on the substrate. A fourth insulation layer, a third insulation layer and a second insulation layer within the first via V1 are etched away to expose a surface of the first region of the first active layer, and the first via V1 is configured such that a first initial signal line formed later is connected with the first region of the first active layer through the via.

In an exemplary implementation, an orthographic projection of the second via V2 on the substrate is within a range of an orthographic projection of the second region of the first active layer (that is, the first region of the second active layer) on the substrate. A fourth insulation layer, a third insulation layer and a third insulation layer within the second via V2 are etched away to expose a surface of the second region of the first active layer (that is, the first region of the second active layer), and the second via V2 is configured such that the first connection electrode formed later is connected with the second region of the first active layer (that is, the first region of the second active layer) through this via.

In an exemplary implementation, an orthographic projection of the third via V3 on the substrate is within a range of an orthographic projection of the first region of the fourth active layer on the substrate. A fourth insulation layer, a third insulation layer and a second insulation layer within the third via V3 are etched away to expose a surface of the first region of the fourth active layer, and the third via V3 is configured such that a third connection line formed later is connected with the first region of the fourth active layer through this via.

In an exemplary implementation, an orthographic projection of the fourth via V4 on the substrate is within a range of an orthographic projection of the second region of the sixth active layer (that is, the second region of the seventh active layer) on the substrate. A fourth insulation layer, a third insulation layer and a second insulation layer within the fourth via V4 are etched away to expose a surface of the second region of the fourth active layer (that is, the second region of the ninth active layer), and the fourth via V4 is configured such that the second connection electrode formed later is connected with the second region of the fourth active layer (that is, the second region of the ninth active layer) through this via.

In an exemplary implementation, an orthographic projection of the fifth via V5 on the substrate is within a range of an orthographic projection of the first region of the fifth active layer on the substrate. A fourth insulation layer, a third insulation layer and a second insulation layer within the fifth via V5 are etched away to expose a surface of the first region of the fifth active layer, and the fifth via V5 is configured such that a fourth connection electrode formed later is connected with the first region of the fifth active layer through this via.

In an exemplary implementation, an orthographic projection of the sixth via V6 on the substrate is within a range of an orthographic projection of the second region of the sixth active layer (i.e., the second region of the seventh active layer) on the substrate. A fourth insulation layer, a third insulation layer and a second insulation layer within the sixth via V6 are etched away to expose a surface of the second region of the sixth active layer (i.e., the second region of the seventh active layer), and the sixth via V6 is configured such that a fifth connection electrode formed later is connected with the second region of the sixth active layer (i.e., the second region of the seventh active layer) through this via.

In an exemplary implementation, an orthographic projection of the seventh via V7 on the substrate is within a range of an orthographic projection of the first region of the seventh active layer on the substrate. A fourth insulation layer, a third insulation layer, and a second insulation layer within the seventh via V7 are etched away to expose a surface of the first region of the seventh active layer, and the seventh via V7 is configured such that a second initial signal line formed later is connected with the first region of the seventh active layer through this via.

In an exemplary implementation, an orthographic projection of the eighth via V8 on the substrate is within a range of an orthographic projection of the first region of the eighth active layer on the substrate. A fourth insulation layer, a third insulation layer, and a second insulation layer within the eighth via V8 are etched away to expose a surface of the first region of the eighth active layer, and the eighth via V8 is configured such that the sixth connection electrode formed later is connected with the first region of the eighth active layer through this via.

In an exemplary implementation, an orthographic projection of the ninth via V9 on the substrate is within a range of an orthographic projection of the first region of the ninth active layer on the substrate. A fourth insulation layer, a third insulation layer, and a second insulation layer within the ninth via V9 are etched away to expose a surface of the first region of the ninth active layer, and the ninth via V9 is configured such that a first reference signal line formed later is connected with the first region of the ninth active layer through this via.

In an exemplary implementation, an orthographic projection of the tenth via V10 on the substrate is located within a range of an orthographic projection of the opening 75 of the third plate 73 on the substrate. A fourth insulation layer and a third insulation layer within the tenth via V10 are etched away to expose a surface of the first plate 71, and the tenth via V10 is configured such that the first connection electrode formed later is connected with the first plate 71 through this via.

In an exemplary implementation, an orthographic projection of the eleventh via V11 on the substrate is within a range of the orthographic projection of the second opening 76 of the fourth plate 74 on the substrate. A fourth insulation layer and a third insulation layer within the eleventh via V11 are etched away to expose a surface of the second plate 72, and the eleventh via V11 is configured such that the second connection electrode formed later is connected with the second plate 72 through this via.

In an exemplary implementation, an orthographic projection of the twelfth via V12 on the substrate is located within a range of an orthographic projection of the first plate connection line 73-1 of the third plate 73 on the substrate. A fourth insulation layer within the twelfth via V12 is etched away to expose a surface of the first plate connection line 73-1, and the twelfth via V12 is configured such that the second connection electrode formed later is connected with the first plate connection line 73-1 through this via.

In an exemplary implementation, an orthographic projection of the thirteenth via V13 on the substrate is within a range of an orthographic projection of the fourth plate 74 on the substrate. A fourth insulation layer within the thirteenth via V13 is etched away to expose a surface of the fourth plate 74, and the thirteenth via V13 is configured such that the first power supply connection line formed later is connected with the fourth plate 74 through this via.

In an exemplary implementation, an orthographic projection of the fourteenth via V14 on the substrate is within a range of an orthographic projection of the first gate electrode 21 on the substrate. A fourth insulation layer and a third insulation layer within the fourteenth via V14 are etched away to expose a surface of the first gate electrode 21, and the fourteenth via V14 is configured such that a fourth scan signal line formed later is connected with the first gate electrode 21 through this via.

In an exemplary implementation, an orthographic projection of the fifteenth via V15 on the substrate is within a range of an orthographic projection of the second gate electrode 22 on the substrate. A fourth insulation layer and a third insulation layer within the fifteenth via V15 are etched away to expose a surface of the second gate electrode 22, and the fifteenth via V15 is configured such that a fifth scan signal line formed later is connected with the second gate electrode 22 through this via.

In an exemplary implementation, an orthographic projection of the sixteenth via V16 on the substrate is within a range of an orthographic projection of the fourth gate electrode 24 on the substrate. A fourth insulation layer and a third insulation layer within the sixteenth via V16 are etched away to expose a surface of the fourth gate electrode 24, and the sixteenth via V16 is configured such that a third scan signal line formed later is connected with the fourth gate electrode 24 through this via.

In an exemplary implementation, an orthographic projection of the seventeenth via V17 on the substrate is within a range of an orthographic projection of the fifth gate electrode 25 on the substrate. A fourth insulation layer and a third insulation layer within the seventeenth via V17 are etched away to expose a surface of the fifth gate electrode 25, and the seventeenth via V17 is configured such that the seventh connection electrode formed later is connected with the fifth gate electrode 25 through this via.

In an exemplary implementation, an orthographic projection of the eighteenth via V18 on the substrate is within a range of an orthographic projection of the sixth gate electrode 26 on the substrate. A fourth insulation layer and a third insulation layer within the eighteenth via V18 are etched away to expose a surface of the sixth gate electrode 26, and the eighteenth via V18 is configured such that the eighteenth connection electrode formed later is connected to the sixth gate electrode 26 through the via V18.

In an exemplary implementation, an orthographic projection of the nineteenth via V19 on the substrate is within a range of an orthographic projection of the ninth gate electrode 29 on the substrate. A fourth insulation layer and a third insulation layer within the nineteenth via V19 are etched away to expose a surface of the ninth gate electrode 29, and the nineteenth via V19 is configured such that a second scan signal line formed later is connected to the ninth gate electrode 29 through this via.

In an exemplary implementation, an orthographic projection of the twentieth via V20 on the substrate is within a range of an orthographic projection of the first light emitting connection block 31-1 of the first light emitting signal line 31 on the substrate. A fourth insulation layer within the twentieth via V20 is etched away to expose a surface of the first light emitting connection block 31-1, and the twentieth via V20 is configured such that the seventh connection electrode formed later is connected with the first light emitting connection block 31-1 through this via.

In an exemplary implementation, an orthographic projection of the twenty-first via V21 on the substrate is within a range of an orthographic projection of the first light emitting connection block 32-1 of the first light emitting signal line 32 on the substrate. A fourth insulation layer within the twenty-first via V21 is etched away to expose a surface of the second light emitting connection block 32-1, and the twenty-first via V21 is configured such that the eighth connection electrode formed later is connected to the second light emitting connection block 32-1 through this via.

In an exemplary implementation, an orthographic projection of the twenty-second via V22 on the substrate is within a range of an orthographic projection of the second reference connection block 92-1 of the second reference signal line 92 on the substrate. A fourth insulation layer within the twenty-second via V22 is etched away to expose a surface of the second reference connection block 92-1, and the twenty-second via V22 is configured such that the sixth connection electrode formed later is connected to the second reference connection block 92-1 through this via

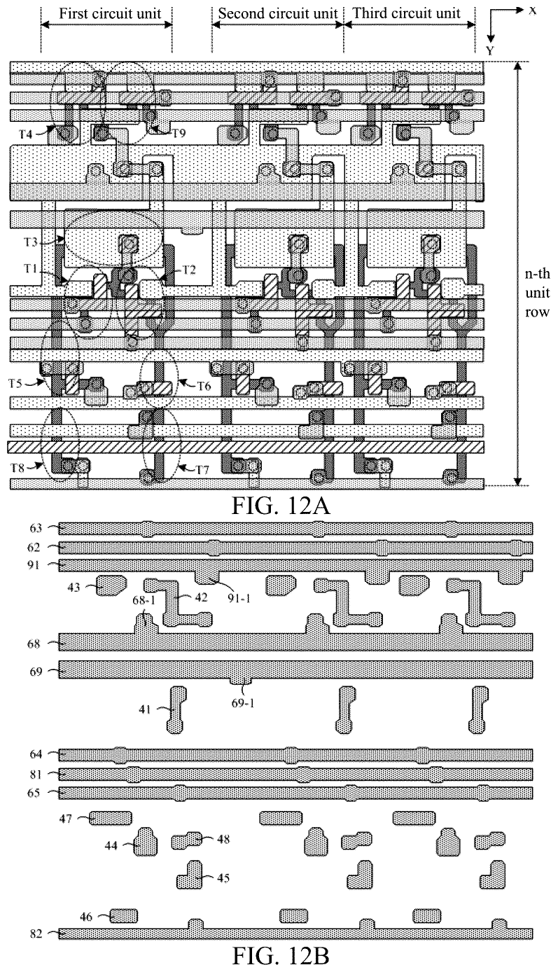

(15) A pattern of a third conductive layer is formed. In an exemplary implementation, forming the third conductive layer may include: a third conductive thin film is deposited on the substrate on which the aforementioned patterns are formed, the third conductive thin film is patterned through a patterning process to form a third conductive layer disposed on the fourth insulation layer, as shown in FIG. 12A and FIG. 12B, wherein FIG. 12B is a schematic diagram of the third conductive layer in FIG. 12A. In an exemplary implementation, the third conductive layer may be referred to as a first source-drain metal (SD1) layer.

In an exemplary implementation, each of patterns of third conductive layers of a plurality of circuit units in the display substrate may include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a second scan signal line 62, a third scan signal line 63, a fourth scan signal line 64, a fifth scan signal line 65, a first power supply connection line 68, a second power supply connection line 69, a first initial signal line 81, a second initial signal line 82, and a first reference signal line 91.

In an exemplary implementation, each of shapes of the second scan signal line 62, the third scan signal line 63, the fourth scan signal line 64, the fifth scan signal line 65, the first power supply connection line 68, the second power supply connection line 69, the first initial signal line 81, the second initial signal line 82, and the first reference signal line 91 may be a shape of line in which a main portion extends along the first direction X. The second scan signal line 62, the third scan signal line 63, and the first reference signal line 91 may be located on a side opposite to the fourth plate 74 in the second direction Y, the fourth scan signal line 64, the fifth scan signal line 65, the first initial signal line 81, and the second initial signal line 82 may be located on a side of the third plate 73 in the second direction Y, the first power supply connection line 68 may be located in a region where the fourth plate 74 is located, the second power supply connection line 69 may be located in a region where the third plate 73 is located, and the second power supply connection line 69 may be located on a side of the first power supply connection line 68 in the second direction Y.

In an exemplary implementation, the first reference signal line 91 may be located on a side opposite to the fourth plate 74 in the second direction Y, the second scan signal line 62 may be located on a side opposite to the first reference signal line 91 in the second direction Y, and the third scan signal line 63 may be located on a side opposite to the second scan signal line 62 in the second direction Y.

In an exemplary implementation, the fourth scan signal line 64 may be located on a side of the third plate 73 in the second direction Y, the first initial signal line 81 may be located on a side of the fourth scan signal line 64 in the second direction Y, the fifth scan signal line 65 may be located on a side of the first initial signal line 81 in the second direction Y, and the second initial signal line 82 may be located on a side of the fifth scan signal line 65 in the second direction Y.

In an exemplary implementation, the first power supply connection line 68 may be located on a side of the fourth plate 74 close to the third plate 73, an orthographic projection of the first power supply connection line 68 on the substrate is overlapped, at least partially, with an orthographic projection of the fourth plate 74 on the substrate, and the first power supply connection line 68 is configured to connect with the first power supply line formed later to form a high-voltage power supply grid structure of a mesh communication structure in the display substrate.

In an exemplary implementation, the second power supply connection line 69 may be located on a side of the third plate 73 close to the fourth plate 74, an orthographic projection of the second power supply connection line 69 on the substrate is overlapped, at least partially, with an orthographic projection of the third plate 73 on the substrate, and the second power supply connection line 69 is configured to connect with a second power supply line formed later to form a lower-voltage power supply grid structure of a mesh communication structure in the display substrate.

In an exemplary implementation, the second scan signal line 62 is connected with a ninth gate electrode 29 in each circuit unit through the nineteenth via V19, thereby the second scan signal line 62 being connected to the ninth gate electrode 29 of the ninth transistor T9 is achieved, and the second scan signal line 62 can control turn-on and turn-off of the ninth transistor T9.

In an exemplary implementation, the fifth scan signal line 65 is connected with a second gate electrode 22 in each circuit unit through the fifteenth via V15, thereby the fifth scan signal line 65 being connected to the second gate electrode 22 of the second transistor T2 is achieved, and the fifth scan signal line 65 can control turn-on and turn-off of the second transistor T2.

In an exemplary implementation, the second scan signal line 62 and the fifth scan signal line 65 may be connected with a same gate drive circuit after extending to a bezel region, so as to achieve output of a same scan signal. That is, the second scan signal line 62 and the fifth scan signal line 65 output a same second scan signal.

In an exemplary implementation, the third scan signal line 63 is connected with a fourth gate electrode 24 in each circuit unit through the sixteenth via V16, thereby the third scan signal line 63 being connected to the fourth gate electrode 24 of the fourth transistor T4 is achieved, and the third scan signal line 63 can control turn-on and turn-off of the fourth transistor T4.

In an exemplary implementation, the fourth scan signal line 64 is connected with a first gate electrode 21 in each circuit unit through the fourteenth via V14, thereby the fourth scan signal line 64 being connected to the first gate electrode 21 of the first transistor T1 is achieved, and the fourth scan signal line 64 can control turn-on and turn-off of the first transistor T1.

In an exemplary implementation, the first initial signal line 81 is connected with a first region of a first active layer in each circuit unit through the first via V1, thereby the first initial signal line 81 being connected to the first electrode of the seventh transistor T1 is achieved, and the first initial signal line 81 can write the first initial signal to the first electrode of the first transistor T1.

In an exemplary implementation, the second initial signal line 82 is connected with a first region of a seventh active layer in each circuit unit through the seventh via V7, thereby the second initial signal line 82 being connected to the first electrode of the seventh transistor T7 is achieved, and the second initial signal line 82 can write the second initial signal to the first electrode of the seventh transistor T7.

In an exemplary implementation, the first reference signal line 91 is connected with a first region of a ninth active layer in each circuit unit through the ninth via V9, thereby the first reference signal line 91 being connected to the first electrode of the ninth transistor T9 is achieved, and the first reference signal line 91 can write the first reference signal to the first electrode of the ninth transistor T9.

In an exemplary implementation, a reference connection block 91-1 is provided on a side of the first reference signal line 91 close to the first power supply connection line 68, a first end of the reference connection block 91-1 is connected with the first reference signal line 91, a second end of the reference connection block 91-1 extends in a direction toward the first power supply connection line 68, and the reference connection block 91-1 is configured to connect with a reference signal connection line formed later.

In an exemplary implementation, the first power supply connection line 68 is connected with a fourth plate 74 in each circuit unit through the thirteenth via V13, thereby the first power supply connection line 68 being connected with the fourth plate 74 is achieved. Since the first power supply connection line 68 is connected with the first power supply line formed subsequently, the first power supply connection line 68 can write the first power supply signal to the upper plate of the second storage capacitor (the first end of the second storage capacitor).

In an exemplary implementation, a first power supply connection block 68-1 is provided on a side of the first power supply connection line 68 away from the second power supply connection line 69, a first end of the first power supply connection block 68-1 is connected with the first power supply connection line 68, and a second end of the first power supply connection block 68-1 extends toward a direction away from the second power supply connection line 69. In an exemplary implementation, on the one hand, the first power supply connection block 68-1 is configured to connect with the fourth plate 74 through the thirteenth via V13. On the other hand, the first power supply connection block 68-1 is configured to connect with the first power supply line formed later.

In an exemplary implementation, in at least one circuit unit, a second power supply connection block 69-1 is provided on a side of the second power supply connection line 69 away from the first power supply connection line 68. A first end of the second power supply connection block 69-1 is connected with the second power supply connection line 69, a second end of the second power supply connection block 69-1 extends in a direction away from the first power supply connection line 68, and the second power supply connection block 69-1 is configured to connect with the second power supply line formed later. In an exemplary implementation, the second power supply connection block 69-1 may be disposed between the first circuit unit and the second circuit unit.

In an exemplary implementation, a shape of the first connection electrode 41 may be a shape of strip in which a main portion extends along the second direction Y, and the first connection electrode 41 may be located between the fourth scan signal line 64 and the second power supply connection line 69. A first end of the first connection electrode 41 is connected with the second region of the first active layer (i.e., the first region of the second active layer) through the second via V2, and a second end of the first connection electrode 41 is connected with the first plate 71 through the tenth via V10. In an exemplary implementation, the first connection electrode 41 enables the second electrode of the first transistor T1, the first electrode of the second transistor T2, the gate electrode of the third transistor T3, and the first plate 71 of the first storage capacitor (i.e., the first end of the first storage capacitor) being at a same potential, and the first connection electrode 41 may serve as the first node N1 of the pixel drive circuit.

In an exemplary implementation, a shape of the second connection electrode 42 may be a shape of polyline in which a main portion extends along the second direction Y, and the second connection electrode 42 may be located between the first reference signal line 91 and the first power supply connection line 68. A first end of the second connection electrode 42 is connected with the second region of the fourth active layer (i.e., the second region of the ninth active layer) through the fourth via V4, a second end of the second connection electrode 42 is connected with the first plate connection line 73-1 through the twelfth via V12, and a third end between the first end and the second end is connected with the second plate 72 through the eleventh via V11. In an exemplary implementation, the second connection electrode 42 enables the second electrode of the fourth transistor T4, the second electrode of the ninth transistor T9, the third plate 73 of the first storage capacitor (i.e., the second end of the first storage capacitor) and the second plate 72 of the second storage capacitor (i.e., the second end of the second storage capacitor) being at a same potential, and the second connection electrode 42 may serve as the fifth node N5 of the pixel drive circuit.

In an exemplary implementation, a shape of the third connection electrode 43 may be rectangular, the third connection electrode 43 may be located between the first reference signal line 91 and the first power supply connection line 68, and the third connection electrode 43 is connected with the first region of the fourth active layer through the third via V3. In an exemplary implementation, the third connection electrode 43 may serve as the first electrode of the fourth transistor T4, and is configured to connect with a data signal line formed later.

In an exemplary implementation, a shape of the fourth connection electrode 44 may be rectangular, the fourth connection electrode 44 may be located between the fifth scan signal line 65 and the second initial signal line 82, and the fourth connection electrode 44 is connected with the first region of the fifth active layer through the fifth via V5. In an exemplary implementation, the fourth connection electrode 44 may serve as the first electrode of the fifth transistor T5, and is configured to connect with the first power supply line formed later.

In an exemplary implementation, a shape of the fifth connection electrode 45 may be “L” shaped, the fifth connection electrode 45 may be located between the fifth scan signal line 65 and the second initial signal line 82, and the fifth connection electrode 45 is connected with the second region of the sixth active layer (i.e., the second region of the seventh active layer) through the sixth via V6. In an exemplary implementation, the fifth connection electrode 45 may serve as the second electrode of the sixth transistor T6 and the second electrode of the seventh transistor T7, and the fifth connection electrode 45 is configured to connect with an anode connection electrode formed later.

In an exemplary implementation, a shape of the sixth connection electrode 46 may be a shape of strip in which a main portion extends along the first direction X, the sixth connection electrode 46 may be located between the fifth scan signal line 65 and the second initial signal line 82, a first end of the sixth connection electrode 46 is connected with the first region of the eighth active layer through the eighth via V8, and a second end of the sixth connection electrode 46 is connected with the second reference connection block 92-1 through the twenty-second via V22. In an exemplary implementation, the sixth connection electrode 46 may serve as the first electrode of the eighth transistor T8. Since the second reference connection block 92-1 is connected with the second reference signal line 92, the second reference signal line 92 being connected to the first electrode of the eighth transistor T8 is achieved, and the second reference signal line 92 in the n-th unit row may write the second reference signal to the first electrode of the eighth transistor T8 in the (n−1)-th unit row.

In an exemplary implementation, a shape of the seventh connection electrode 47 may be a shape of strip in which a main portion extends along the first direction X, and the seventh connection electrode 47 may be located between the fifth scan signal line 65 and the second initial signal line 82. A first end of the seventh connection electrode 47 is connected with the fifth gate electrode 25 through the seventeenth via V17, and a second end of the seventh connection electrode 47 is connected with the first light emitting connection block 31-1 through the twentieth via V20. Since the first light emitting connection block 31-1 is connected with the first light emitting signal line 31, the first light emitting signal line 31 being connected to the fifth gate electrode 25 of the fifth transistor T5 is achieved, and the first light emitting signal line 31 can control turn-on and turn-off of the fifth transistor T5.

In an exemplary implementation, a shape of the eighth connection electrode 48 may be a shape of strip in which a main portion extends along the first direction X, and the eighth connection electrode 48 may be located between the fifth scan signal line 65 and the second initial signal line 82. A first end of the eighth connection electrode 48 is connected with the sixth gate electrode 26 through the eighteenth via V18, and a second end of the eighth connection electrode 48 is connected with the second light emitting connection block 32-1 through the twenty-first via V21. Since the second light emitting connection block 32-1 is connected with the second light emitting signal line 32, the second light emitting signal line 32 being connected to the sixth gate electrode 26 of the sixth transistor T6 is achieved, and the second light emitting signal line 32 can control turn-on and turn-off of the sixth transistor T6.

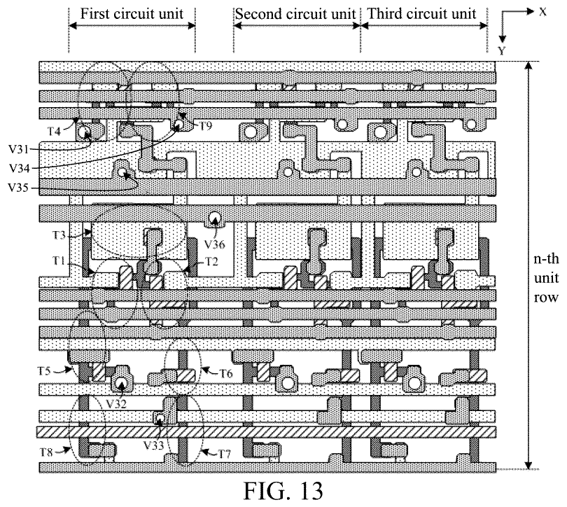

(16) A pattern of a fifth insulation layer is formed. In an exemplary implementation, forming the pattern of the fifth insulation layer may include: a fifth insulation thin film is deposited on the substrate on which the aforementioned patterns are formed, the fifth insulation thin film is patterned through a patterning process to form a fifth insulation layer that covers the third conductive layer, wherein a plurality of vias are disposed on each circuit unit, as shown in FIG. 13.

In an exemplary implementation, a plurality of vias of each circuit unit in the display substrate includes, at least, a thirty-first via V31, a thirty-second via V32, a thirty-third via V33, a thirty-fourth via V34, and a thirty-fifth via V35.

In an exemplary implementation, an orthographic projection of the thirty-first via V31 on the substrate is located within a range of an orthographic projection of the third connection electrode 43 on the substrate, a fifth insulation layer within the thirty-first via V31 is removed to expose a surface of the third connection electrode 43, and the thirty-first via V31 is configured such that the data signal line formed later is connected with the third connection electrode 43 through this via.

In an exemplary implementation, an orthographic projection of the thirty-second via V32 on the substrate is located within a range of an orthographic projection of the fourth connection electrode 44 on the substrate, a fifth insulation layer within the thirty-second via V32 is removed to expose a surface of the fourth connection electrode 44, and the thirty-second via V32 is configured such that the first power supply line formed later is connected with the fourth connection electrode 44 through this via.

In an exemplary implementation, an orthographic projection of the thirty-third via V33 on the substrate is located within a range of an orthographic projection of the fifth connection electrode 45 on the substrate, a fifth insulation layer within the thirty-third via V33 is removed to expose a surface of the fifth connection electrode 45, and the thirty-third via V33 is configured such that the anode connection electrode formed later is connected with the fifth connection electrode 45 through this via.

In an exemplary implementation, an orthographic projection of the thirty-fourth via V34 on the substrate is within a range of an orthographic projection of the reference connection block 91-1 of the first reference signal line 91 on the substrate. A fifth insulation layer within the thirty-fourth via V34 is removed to expose a surface of the reference connection block 91-1, and the thirty-fourth via V34 is configured such that the reference signal connection line formed later is connected with the reference connection block 91-1 through this via.

In an exemplary implementation, an orthographic projection of the thirty-fifth via V35 on the substrate is within a range of an orthographic projection of the first power supply connection block 68-1 of the first power supply connection line 68 on the substrate, a fifth insulation layer within the thirty-fifth via V35 is removed to expose a surface of the first power supply connection block 68-1, and the thirty-fifth via V35 is configured such that the first power supply line formed later is connected with the first power supply connection block 68-1 through the via V35.

In an exemplary implementation, at least one circuit unit may further include a thirty-sixth via V36. An orthographic projection of the thirty-fifth via V36 on the substrate is within a range of an orthographic projection of the second power supply connection block 69-1 of the second power supply connection line 69 on the substrate, a fifth insulation layer within the thirty-sixth via V36 is removed to expose a surface of the second power supply connection block 69-1, and the thirty-sixth via V36 is configured such that the second power supply line formed later is connected with the second power supply connection block 69-1 through this via. In an exemplary implementation, the thirty-sixth via V36 may be located between the first circuit unit and the second circuit unit.

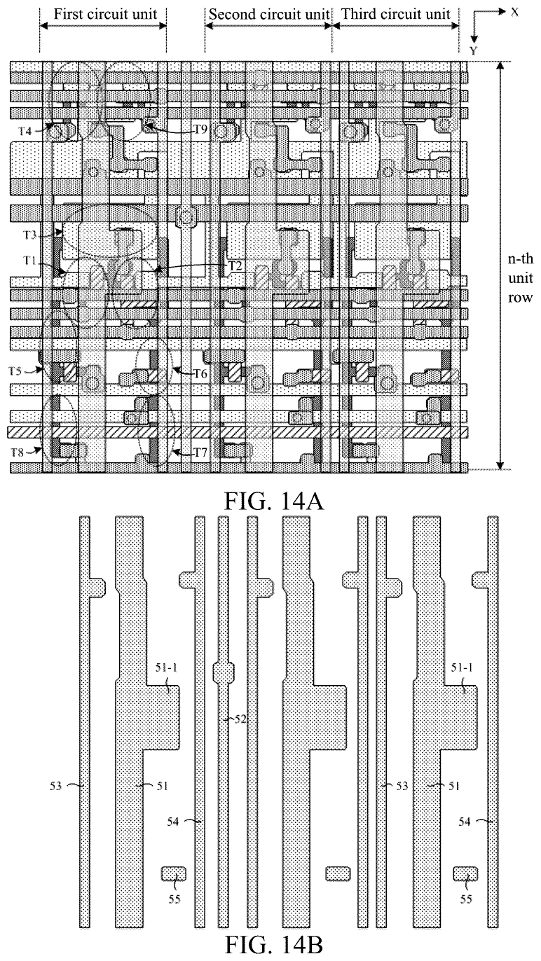

(17) A pattern of a fourth conductive layer is formed. In an exemplary implementation, forming the pattern of the fourth conductive layer may include: a fourth conductive thin film is deposited on the substrate on which the aforementioned patterns are formed, the fourth conductive thin film is patterned through a patterning process to form a fourth conductive layer disposed on the fifth insulation layer, as shown in FIG. 14A and FIG. 14B, wherein FIG. 14B is a schematic diagram of the fourth conductive layer in FIG. 14A. In an exemplary implementation, the fourth conductive layer may be referred to as a second source-drain metal (SD2) layer.

In an exemplary implementation, each of patterns of fourth conductive layers of a plurality of circuit units in the display substrate may include a first power supply line 51, a data signal line 53, a reference signal connection line 54, and an anode connection electrode 55.

In an exemplary implementation, each of shapes of the first power supply line 51, the data signal line 53, and the reference signal connection line 54 may be a shape of strip in which a main portion extends along the second direction Y, the first power supply line 51 may be located on a side of the data signal line 53 in the first direction X, and the reference signal connection line 54 may be located on a side of the first power supply line 51 in the first direction X. That is, the first power supply line 51 may be located between the data signal line 53 and the reference signal connection line 54.

In an exemplary implementation, a shape of the first power supply line 51 may be a shape of polyline in which a main portion extending along the second direction Y. On one hand, the first power supply line 51 is connected with the fourth connection electrode 44 through the thirty-second via V32, and on the other hand, the first power supply line 51 is connected with the second power supply connection electrode 68-1 through the thirty-fifth via V35. Since the fourth connection electrode 44 is connected with the first region of the fifth active layer through a via, writing of the first power supply signal to the first electrode of the fifth transistor T5 by the first power supply line 51 is achieved. Since the first power supply connection block 68-1 is connected with the first power supply connection line 68, the first power supply connection line 68 in which a main portion extends along the first direction X and the first power supply line 51 in which a main portion extends along the second direction Y are connected to each other, so that the first power supply line 51 and the first power supply connection line 68 form a mesh structure for transmitting the first power supply signal in the display substrate, which can not only effectively reduce a resistance of the first power supply line 51 and reduce the voltage drop of the first power supply signal, but also effectively improve uniformity of the first power supply signal in the display substrate, effectively improve display uniformity and improve the display quality.

In an exemplary implementation, a power supply shield block 51-1 is provided on a side of the first power supply line 51 close to the reference signal connection line 54, a first end of the power supply shield block 51-1 is connected with the first power supply line 51, and a second end of the power supply shield block 51-1 extends in a direction toward the reference signal connection line 54. A shape of the power supply shield block 51-1 may be rectangular, and an orthographic projection of the power supply shield block 51-1 on the substrate is overlapped, at least partially, with the orthographic projection of the first connection electrode 41 on the substrate. Since the first connection electrode 41 serves as the first node N1 in the pixel drive circuit, the power supply shield block 51-1 which is at a constant voltage can effectively shield an influence of other signals in the pixel drive circuit on the first node N1, thereby avoiding an influence of other signals (such as data voltage jump) on a potential at the first node N1 in the pixel drive circuit, and improving the display effect.

In an exemplary implementation, the first power supply line 51 and the power supply shield block 51-1 may be connected to each other to form an integral structure.

In an exemplary implementation, the orthographic projection of the power supply shield block 51-1 on the substrate may include the orthographic projection of the first connection electrode 41 on the substrate.

In an exemplary implementation, the orthographic projection of the first power supply line 51 on the substrate is overlapped, at least partially, with an orthographic projection of the second connection electrode 42 on the substrate. Since the second connection electrode 42 serves as the fifth node N5 in the pixel drive circuit, the first power supply line 51 which is at a constant voltage can effectively shield an influence of other signals in the pixel drive circuit on the fifth node N5, thereby avoiding an influence of other signals on a potential at the fifth node N5 in the pixel drive circuit, and improving the display effect.

In an exemplary implementation, the first power supply line 51 may be of an unequal width design, and the first power supply line 51 with the unequal width design can not only facilitate a layout of a pixel structure, but also reduce a parasitic capacitance between the first power supply line and a data signal line.

In an exemplary implementation, a shape of the data signal line 53 may be a shape of straight line in which a main portion extends along the second direction Y, and the data signal line 53 is connected with the third connection electrode 43 through the thirty-first via V31. Since the third connection electrode 43 is connected to the first region of the fourth active layer through a via, writing of the data signal to the first electrode of the fourth transistor T4 by the data signal line 53 is achieved.

In an exemplary implementation, a shape of the reference signal connection line 54 may be a shape of straight line in which a main portion extends along the second direction Y, and the reference signal connection line 54 is connected with the reference connection block 91-1 through the thirty-fourth via V34. Since the reference connection block 91-1 is connected with the first reference signal line 91, the first reference signal line 91 in which the main portion extends along the first direction X and the reference signal connection line 54 in which the main portion extends along the second direction Y are connected to each other, so that the first reference signal line 91 and the reference signal connection line 54 form a mesh structure for transmitting the first reference signal in the display substrate, which can not only effectively reduce the resistance of the first reference signal line and reduce the voltage drop of the first reference signal, but also effectively improve uniformity of the first reference signal in the display substrate, effectively improve the display uniformity and improve the display quality.

In an exemplary implementation, a shape of the anode connection electrode 55 may be rectangular, and the anode connection electrode 55 is connected with the fifth connection electrode 45 through the thirty-third via V33. Since the fifth connection electrode 45 is connected with the second region of the sixth active layer (i.e., the second region of the seventh active layer) through a via, the anode connection electrode 55 being connected with the second electrode of the sixth transistor T6 and the second electrode of the seventh transistor T7 is achieved. In an exemplary implementation, the anode connection electrode 55 is configured to connect with an anode formed later, thereby the pixel drive circuit can drive a light emitting device.

In an exemplary implementation, an orthographic projection of the anode connection electrode 55 on the substrate is overlapped, at least partially, with an orthographic projection of the repair line 33 on the substrate.

In an exemplary implementation, the fourth conductive layer in the at least one circuit unit may further include a second power supply line 52. A shape of the second power supply line 52 may be a shape of straight line in which a main portion extends along the second direction Y, and the second power supply line 52 is connected with the second power supply connection block 69-1 through the thirty-sixth via V36. Since the second power supply connection block 69-1 is connected with the second power supply connection line 69, the second power supply connection line 69 in which the main portion extends along the first direction X and the second power supply line 52 in which the main portion extends along the second direction Y are connected to each other, so that the second power supply line 52 and the second power supply connection line 69 form a mesh structure for transmitting the second power supply signal in the display substrate, which can not only effectively reduce a resistance of the second power supply line 52 and reduce the voltage drop of the second power supply signal, but also effectively improve uniformity of the second power supply signal in the display substrate, effectively improve display uniformity and improve the display quality. In an exemplary implementation, the second power supply line 52 may be located between a reference signal connection line 54 of the first circuit unit and a data signal line 53 of the second circuit unit.

In an exemplary implementation, the first power supply connection line 68 of the third conductive layer may be disposed in each unit row, and the first power supply line 51 of the fourth conductive layer may be disposed in each unit column, and a plurality of first power supply connection lines 51 are connected, respectively, to a plurality of first power supply connection lines 68 to form a mesh structure for transmitting the first power supply signal.

In an exemplary implementation, the first reference signal line 91 of the third conductive layer may be disposed in each unit row, the reference signal connection line 54 of the fourth conductive layer may be disposed in each unit column, and a plurality of first reference signal lines 91 are connected, respectively, to a plurality of reference signal connection lines 54 to form a mesh structure for transmitting the first reference signal.

In an exemplary embodiment, the second power supply connection line 69 of the third conductive layer may be disposed in each unit row, and the second power supply lines 52 of the fourth conductive layer may be disposed every two unit columns, and a plurality of the second power supply connection lines 52 are connected, respectively, to a plurality of the second power supply connection lines 69 to form a mesh structure for transmitting the second power supply signal.

A subsequent manufacturing process may include forming a pattern of a first planarization layer, the first planarization layer is provided with a plurality of anode vias, orthographic projections of the anode vias on the substrate are within a range of the orthographic projection of the anode connection electrode on the substrate. A first planarization layer within the anode vias is removed to expose a surface of the anode connection electrode, and the anode vias are configured such that the anode formed later is connected with the anode connection electrode through the anode vias.

At that point, the drive circuit layer in this embodiment is manufactured on the substrate. In an exemplary implementation, after the drive circuit layer is manufactured, a light emitting structure layer and an encapsulation structure layer may be sequentially manufactured on the drive circuit layer, which is not repeated here.

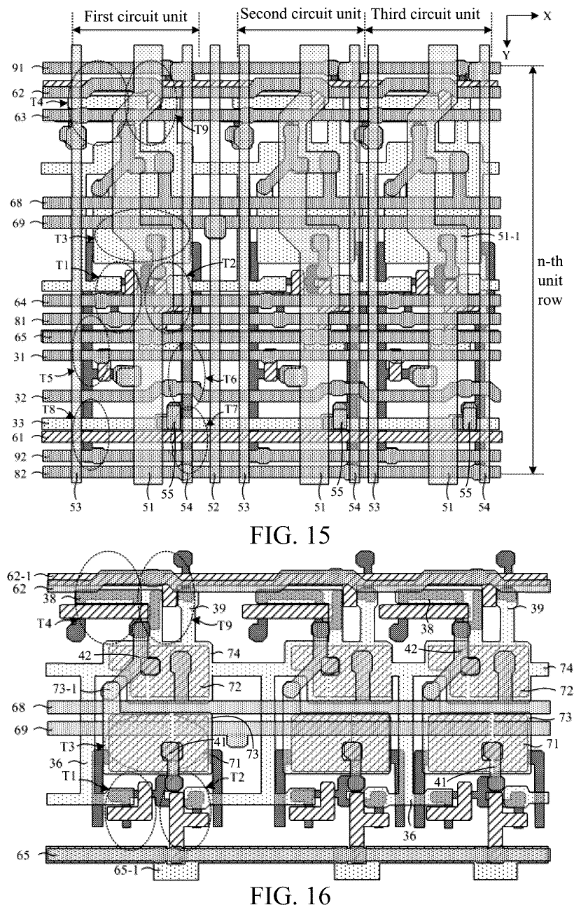

FIG. 15 is a schematic diagram of a planar structure of another display substrate according to an exemplary embodiment of the present disclosure, illustrating a structure of a pixel drive circuit in three circuit units (a first circuit unit, a second circuit unit, and a third circuit unit) in the display substrate, and FIG. 16 is a schematic diagram of a structure of a second scan signal line and a fifth scan signal line in FIG. 15. As shown in FIGS. 15 and 16, a main structure of the pixel drive circuit in this exemplary embodiment is substantially the same as the structure in the foregoing embodiment except that the second scan connection line 62 and the fifth scan signal line 65 in this embodiment are scan signal lines in a double-layer structure.

In an exemplary implementation, a first power supply line 51 extending along a second direction Y and a first power supply connection line 68 extending along a first direction X are connected to each other to form a mesh structure for transmitting a first power supply signal, a second power supply line 52 extending along the second direction Y and a second power supply connection line 69 extending along the first direction X are connected to each other to form a mesh structure for transmitting a second power supply signal, and a reference signal connection line 54 extending along the second direction Y and a first reference signal line 91 extending along the first direction X are connected to each other to form a mesh structure for transmitting a first reference signal.

In an exemplary implementation, the at least one circuit unit may further include a first shield electrode 36, a third shield electrode 38, and a fourth shield electrode 39, wherein an orthographic projection of the first shield electrode 36 on the substrate is overlapped, at least partially, with an orthographic projection of a semiconductor layer, which is located between two gate electrodes of a first transistor T1, on the substrate. The orthographic projection of the first shield electrode 36 on the substrate is overlapped, at least partially, with an orthographic projection of a semiconductor layer, which is located between two gate electrodes of a second transistor T2, on the substrate. An orthographic projection of the third shield electrode 38 on the substrate is overlapped, at least partially, with an orthographic projection of a semiconductor layer, which is located between two gate electrodes of a fourth transistor T4, on the substrate. An orthographic projection of the fourth shield electrode 39 on the substrate is overlapped, at least partially, with an orthographic projection of a semiconductor layer, which is located between two gate electrodes of a ninth transistor T9, on the substrate Since a structure of an active layer structure of the fourth transistor T4 is different from a structure of an active layer of the ninth transistor T9 in this embodiment, no second shield electrode is provided in this embodiment.

In an exemplary implementation, a first scan signal line 61 may be disposed in a first conductive layer, a repair line 33 may be disposed in a second conductive layer, a first light emitting signal line 31, a second light emitting signal line 32, a second scan signal line 62, a third scan signal line 63, a fourth scan signal line 64, a fifth scan signal line 65, the first power supply connection line 68, the second power supply connection line 69, a first initial signal line 81, a second initial signal line 82, the first reference signal line 91 and a second reference signal line 92 may be disposed in a third conductive layer, and the first power supply line 51, the second power supply line 52, a data signal line 53, the reference signal connection line 54 and an anode connection electrode 55 may be disposed in a fourth conductive layer.

In an exemplary implementation, a drive circuit layer may further include a second scan connection line 62-1, a shape of the second scan connection line 62-1 may be a shape of line in which a main portion extends along the first direction X, an orthographic projection of the second scan connection line 62-1 on the substrate is overlapped, at least partially, an orthographic projection of the second scan signal line 62 on the substrate, and the second scan signal line 62 and the second scan connection line 62-1 are connected to each other to form scan signal lines in a double-layer structure.

In an exemplary implementation, the second scan signal line 62 and the second scan connection line 62-1 may be disposed in different conductive layers, and the second scan signal line 62 may be connected with the second scan connection line 62-1 through a via.

In an exemplary implementation, the second scan connection line 62-1 may be disposed in the first conductive layer, and the second scan signal line 62 may be disposed in the third conductive layer.

In an exemplary implementation, the drive circuit layer may further include a fifth scan connection line 65-1, a shape of the fifth scan connection line 65-1 may be a shape of line in which a main portion extends along the first direction X, an orthographic projection of the fifth scan connection line 65-1 on the substrate is overlapped, at least partially, an orthographic projection of the fifth scan signal line 65 on the substrate, and the fifth scan signal line 65 and the fifth scan connection line 65-1 are connected to each other to form scan signal lines in a double-layer structure.

In an exemplary implementation, the fifth scan signal line 65 and the fifth scan connection line 65-1 may be disposed in different conductive layers, and the fifth scan signal line 65 may be connected with the fifth scan connection line 65-1 through a via.

In an exemplary implementation, the fifth scan connection line 65-1 may be disposed in the second conductive layer, and the fifth scan signal line 65 may be disposed in the third conductive layer.

In an exemplary implementation, a manufacturing process for the display substrate in this embodiment may include the following acts.

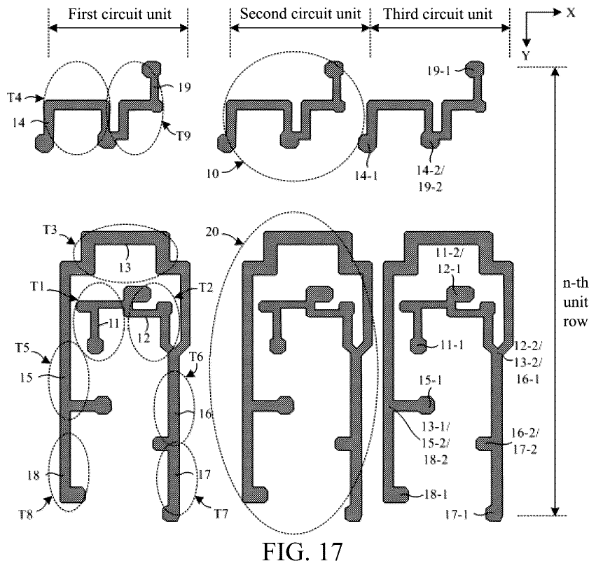

(21) A pattern of a semiconductor layer is formed. In an exemplary implementation, forming the pattern of the semiconductor layer may include: a first insulation thin film and a semiconductor thin film are deposited sequentially on a substrate, and the semiconductor thin film is patterned through a patterning process to form a first insulation layer that covers the substrate, and a semiconductor layer disposed on the first insulation layer, as shown in FIG. 17.

In an exemplary implementation, a semiconductor layer of each circuit unit in the display substrate may include, at least, a first active layer 11 of a first transistor T1, a second active layer 12 of a second transistor T2, a third active layer 13 of a third transistor T3, a fourth active layer 14 of a fourth transistor T4, a fifth active layer 15 of a fifth transistor T5, a sixth active layer 16 of a sixth transistor T6, a seventh active layer 17 of a seventh transistor T7, an eighth active layer 18 of an eighth transistor T8 and a ninth active layer 19 of a ninth transistor T9, and the first to third active layers 11 to 13 and the fifth to eighth active layers 15 to 18 may be connected to each other to form an integral structure, and the fourth and ninth active layers 14 and 19 may be connected to each other to form an integral structure.

In an exemplary embodiment, a structure and a connection relationship of the first to the ninth active layers 11 to 19 are substantially the same as the structure and the connection relationship in the foregoing embodiments, except that a shape of the fourth active layer 14 may be “n” shaped, a first region 14-1 of the fourth active layer may be located on a side of a channel region of the fourth active layer close to the third active layer 13, and a shape of the ninth active layer 19 may be in a polyline shape, and a first region 19-1 of the ninth active layer may be located on a side of a channel region of the ninth active layer away from the third active layer 13.

In an exemplary implementation, the semiconductor layer of the at least one circuit unit may include, at least, a first active pattern 10 and a second active pattern 20, the first active pattern 10 may include the active layer of the fourth transistor T4 and the active layer of the ninth transistor T9, and the second active pattern 20 may include the active layers of the first to third transistors T1 to T3 and the active layers of the fifth to eighth transistors T5 to T8.

In an exemplary implementation, in the at least one circuit unit, the first active pattern 10 is spaced from the second active pattern 20. That is, the active layer of the transistor in the first active pattern 10 is not connected to the active layer of the transistor in the second active pattern 20.

In an exemplary implementation, in at least one unit row, semiconductor layers in circuit units adjacent in the first direction X are spaced from each other. That is, a semiconductor layer of a first circuit unit in the n-th unit row is not connected to a semiconductor layer of a second circuit unit in the n-th unit row, and the semiconductor layer of the second circuit unit in the n-th unit row is not connected to a semiconductor layer of a third circuit unit in the n-th unit row.

In an exemplary implementation, in at least one unit column, semiconductor layers in circuit units adjacent in the second direction Y are spaced from each other. That is, a semiconductor layer of a first circuit unit in the (n−1)-th unit row is not connected to a semiconductor layer of a first circuit unit in the n-th unit row, and the semiconductor layer of the first circuit unit in the n-th unit row is not connected to a semiconductor layer of a first circuit unit in the (n+1)-th unit row.

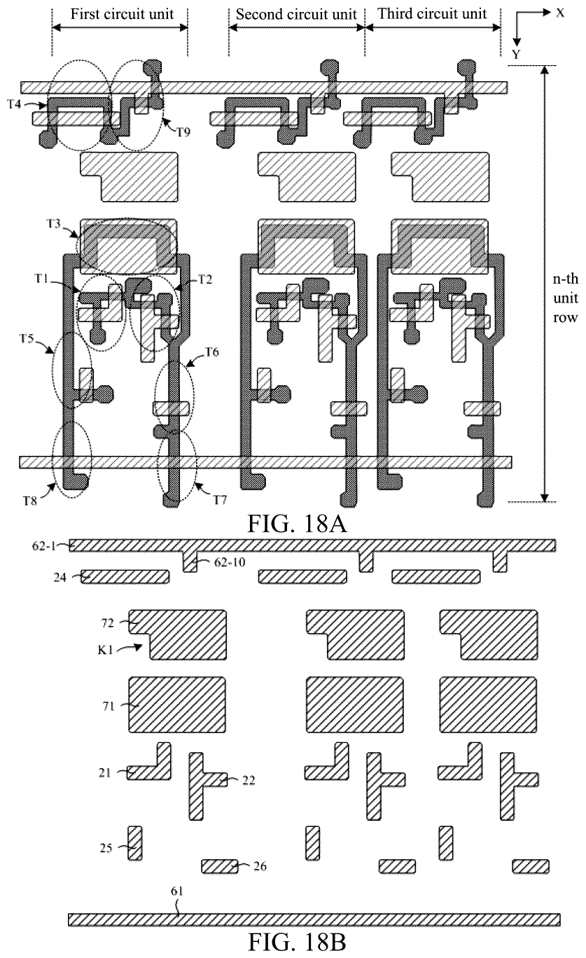

(22) A pattern of a first conductive layer is formed. In an exemplary implementation, forming the pattern of the first conductive layer may include: a second insulation thin film and a first conductive thin film are deposited sequentially on the substrate on which the aforementioned patterns are formed, and the first conductive thin film is patterned through a patterning process to form a second insulation layer that covers the pattern of the semiconductor layer, and a pattern of a first conductive layer disposed on the second insulation layer, as shown in FIGS. 18A and 18B, wherein FIG. 18B is a schematic diagram of the first conductive layer in FIG. 18A.

In an exemplary implementation, a pattern of a first conductive layer of each circuit unit in the display substrate includes, at least, a first gate electrode 21, a second gate electrode 22, a fourth gate electrode 24, a fifth gate electrode 25, a sixth gate electrode 26, a first scan signal line 61, a second scan connection line 62-1, a first plate 71 of a first storage capacitor, and a second plate 72 of a second storage capacitor.

In the exemplary embodiment, a structure and a connection relationship of the first gate electrode 21, the second gate electrode 22, the fifth gate electrode 25, the sixth gate electrode 26, the first scan signal line 61, and the first plate 71 of the first storage capacitor are substantially the same as the structure and the connection relationship in the foregoing embodiments.

In an exemplary embodiment, a shape of the fourth gate electrode 24 may be a shape of strip extending along the first direction X, the fourth gate electrode 24 may be located between the second scan connection line 62-1 and the second plate 72, and a region where the fourth gate electrode 24 is overlapped with the fourth active layer may serve as a gate electrode of the fourth transistor T4 in a double-gate structure.

In an exemplary embodiment, a shape of the second scan connection line 62-1 may be a shape of line extending along the first direction X, and the second scan connection line 62-1 may be located on a side opposite to the second plate 72 in the second direction Y. A gate block 62-10 is provided on a side of the second scan connection line 62-1 close to the second plate 72, a first end of the gate block 62-10 is connected with the second scan connection line 62-1, a second end of the gate block 62-10 extends in a direction toward the second plate 72, and a region where the second scan connection line 62-1 and the gate block 62-10 are overlapped with the ninth active layer may serve as a gate electrode of the ninth transistor T9 in a double-gate structure. In an exemplary implementation, the second scan connection line 62-1 may serve as a lower layer signal line of the second scan signals line in the double-layer structure.

In an exemplary implementation, a shape of the second plate 72 of the second storage capacitor may be a shape of rectangle in which corners of the rectangle may be chamfered, and the second plate 72 may be located between the first plate 71 and the fourth gate electrode 24, and an orthographic projection of the second plate 72 on the substrate is not overlapped with an orthographic projection of the semiconductor layer on the substrate. In an exemplary implementation, the second plate 72 may serve as a lower plate of the second storage capacitor.

In an exemplary implementation, a first groove K1 is provided on a side of the second plate 72 adjacent to the first plate 71, and is configured to accommodate a first plate connection line 73-1.

Different from the foregoing embodiments, the second scan connection line 62-1 is disposed in the first conductive layer in this embodiment. Therefore, no ninth gate electrode is provided.

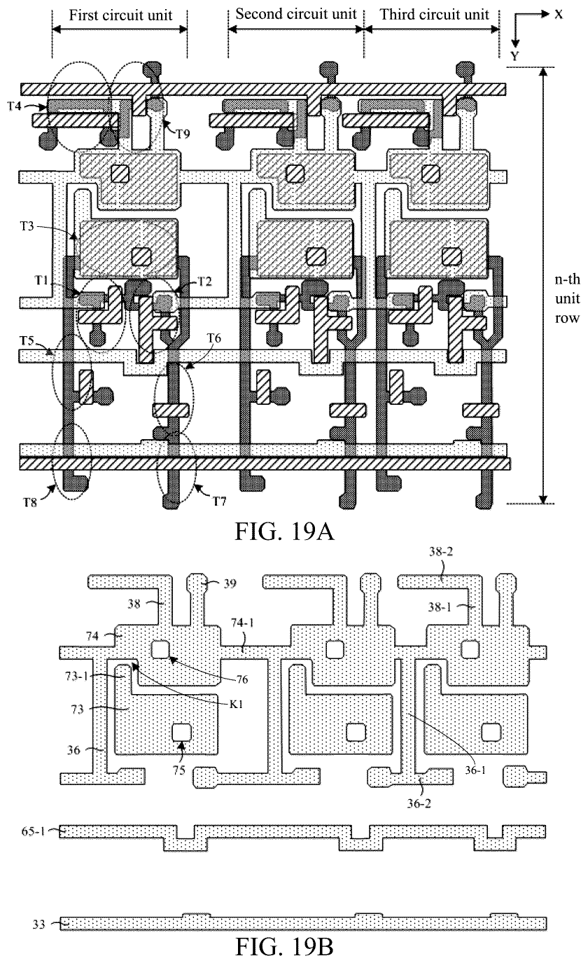

(23) A pattern of a second conductive layer is formed. In an exemplary implementation, forming the pattern of the second conductive layer may include: a third insulation thin film and a second conductive thin film are sequentially deposited on the substrate on which the aforementioned patterns are formed, and the second conductive thin film is patterned through a patterning process to form a third insulation layer that covers the first conductive layer, and a pattern of a second conductive layer disposed on the third insulation layer, as shown in FIGS. 19A and 19B, wherein FIG. 19B is a schematic diagram of the second conductive layer in FIG. 19A.

In an exemplary implementation, a second conductive layer pattern of each circuit unit in the display substrate includes, at least, a repair line 33, a first shield electrode 36, a third shield electrode 38, a fourth shield electrode 39, a fifth scan connection line 65-1, a third plate 73 of the first storage capacitor, and a fourth plate 74 of the second storage capacitor.

In an exemplary implementation, each of shapes of the fifth scan connection line 65-1 and the repair line 33 may be a shape of line in which a main portion extends along the first direction X, the fifth scan connection line 65-1 may be located between the first gate electrode 21 and the fifth gate electrode 25, and the repair line 33 may be located between the fifth gate electrode 25 and the first scan signal line 61.

In an exemplary implementation, the fifth scan connection line 65-1 may include a straight line segment and a bent segment, a shape of the straight line segment may be a shape of straight line extending along the first direction X, and the bent segment protrudes toward the repair line 33 to stagger the second gate electrode 22, so that an orthographic projection of the fifth scan connection line 65-1 on the substrate is not overlapped with an orthographic projection of the second gate electrode 22 on the substrate. In an exemplary implementation, the fifth scan connection line 65-1 may serve as a lower layer signal line of a fifth scan signal line in a double-layer structure.

In the exemplary implementation, a position and a structure of the repair line 33 are substantially the same as the position and the structure in the foregoing embodiments.

In an exemplary implementation, a contour shape of the third plate 73 of the first storage capacitor may be substantially similar to the shape of the first plate 71, an orthographic projection of the third plate 73 on the substrate is overlapped, at least partially, with an orthographic projection of the first plate 71 on the substrate, the third plate 73 may serve as an upper plate of the first storage capacitor, and the first plate 71 and the third plate 73 form the first storage capacitor C1 of the pixel drive circuit.

In an exemplary implementation, a contour shape of the fourth plate 74 of the second storage capacitor may be substantially similar to the shape of the first plate 72, an orthographic projection of the fourth plate 74 on the substrate is overlapped, at least partially, with an orthographic projection of the second plate 72 on the substrate, the fourth plate 74 may serve as an upper plate of the second storage capacitor, and the second plate 72 and the fourth plate 74 form the second storage capacitor C2 of the pixel drive circuit.

In an exemplary implementation, a first plate connection line 73-1 is provided on a side of the third plate 73 close to the fourth plate 74, a first end of the first plate connection line 73-1 is connected with the third plate 73, a second end of the first plate connection line 73-1 extends toward the fourth plate 74, and the second end of the first plate connection line 73-1 is located in the first groove K1 formed in the fourth plate 74, and a position, a connection structure and a function of the first plate connection line 73-1 are substantially the same as those in the foregoing embodiments.

In an exemplary implementation, a second plate connection line 74-1 may be provided on a side of the fourth plate 74 in the first direction X or on an opposite side of the fourth plate 74 in the first direction X, a position, a connection structure and a function of the second plate connection line 74-1 are substantially the same as those in the foregoing embodiments.

In an exemplary implementation, a first opening 75 is provided in a third plate 73 of each circuit unit, and a second opening 76 is provided in a fourth plate 74 of each circuit unit. Positions, connection structures and functions of the first opening 75 and the second opening 76 are substantially the same as those in the foregoing embodiments.

In an exemplary embodiment, a shape of the first shield electrode 36 may be “T” shaped, the first shield electrode 36 may be located near the fifth scan connection line 65-1 in the fourth plate 74, may be disposed in each circuit unit. The “T” shaped first shield electrode 36 may include a first extension segment 36-1 and a first shield segment 36-2, positions, connection structures and functions of the first extension segment 36-1 and the first shield segment 36-2 are substantially the same as those in the foregoing embodiments.

In an exemplary implementation, a shape of the third shield electrode 38 may be “L” shaped, the third shield electrode 38 may be located on a side of the fourth plate 74 close to the second scan connection line 62-1, and may be disposed in each circuit unit. The third shield electrode 38 may include a third extension 38-1 and a third shield segment 38-2, a first end of the third extension 38-1 is connected with the fourth plate 74, the third extension 38-1 is connected with the third shield segment 38-2 after extending toward the second scan connection line 62-1. A shape of the third shield segment 38-2 may be a shape of strip extending along the first direction X, an orthographic projection of the third shield segment 38-2 on the substrate is overlapped, at least partially, with an orthographic projection of a fourth active layer between two gate electrodes of the fourth transistor T4 in the circuit unit on the substrate, and the third shield electrode 38 is configured to shield an influence of data voltage jump on the fourth transistor T4 to avoid the data voltage jump affecting a normal operation of the pixel drive circuit, and improve a display effect.

In an exemplary implementation, a shape of the fourth shield electrode 39 may be a shape of strip extending along the second direction Y, the fourth shield electrode 39 may be located on a side of the fourth plate 74 close to the second scan connection line 62-1, and may be disposed in each circuit unit. A first end of the fourth shield electrode 39 is connected with the fourth plate 74, and a second end of the fourth shield electrode 39 extends toward the second scan connection line 62-1. An orthographic projection of the second end of the fourth shield electrode 39 on the substrate is overlapped, at least partially, with an orthographic projection of a ninth active layer between two gate electrodes of the ninth transistor T9 in this circuit unit on the substrate. In an exemplary implementation, the fourth shield electrode 39 is configured to shield an influence of data voltage jump on the ninth transistor T9, to avoid the data voltage jump affecting the normal operation of the pixel drive circuit, and to improve the display effect.

In an exemplary implementation, the fourth plate 74, the first shield electrode 36, the third shield electrode 38 and the fourth shield electrode 39 may be connected to each other to form an integral structure.

Different from the foregoing embodiments, the second scan connection line 62-1 is disposed in the second conductive layer in this embodiment, and no second reference signal line, first light emitting signal line, or second light emitting signal line is provided in a lateral direction.

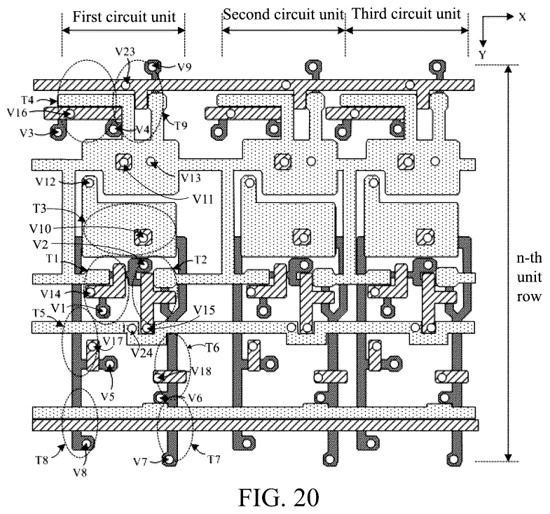

(24) A pattern of a fourth insulation layer is formed. In an exemplary implementation, forming the pattern of the fourth insulation layer may include: a fourth insulation thin film is deposited on the substrate on which the aforementioned patterns are formed, and the fourth insulation thin film is patterned through a patterning process to form a fourth insulation layer that covers the second conductive layer, wherein a plurality of vias are disposed in each circuit unit, as shown in FIG. 20.

In an exemplary implementation, the plurality of vias of each circuit unit in the display substrate at least include a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a twenty-third via V23, and a twenty-fourth via V24.

In an exemplary implementation, positions, connection structures and functions of the first to eighteenth vias V1 to V18 are substantially the same as the positions, the connection structures and the functions in the foregoing embodiments, except that the eighth via V8 is configured to connect a second reference signal line formed later with a first region of the eighth active layer through this via, the seventeenth via V17 is configured to connect with a first light emitting signal line formed later with the fifth gate electrode 25 through this via, and the eighteenth via V18 is configured to connect a second light emitting signal line formed later with the sixth gate electrode 26 through this via.

In an exemplary implementation, an orthographic projection of the twenty-third via V23 on the substrate is within a range of an orthographic projection of the second scan connection line 62-1 on the substrate, a fourth insulation layer and a third insulation layer within the twenty-third via V23 are etched away to expose a surface of the second scan connection line 62-1, and the twenty-third via V23 is configured to connect the second scan signal line formed later with the second scan connection line 62-1 through this via.

In an exemplary implementation, an orthographic projection of the twenty-fourth via V24 on the substrate is within a range of an orthographic projection of the fifth scan connection line 65-1 on the substrate, a fourth insulation layer within the twenty-fourth via V24 is etched away to expose a surface of the fifth scan connection line 65-1, and the twenty-fourth via V24 is configured to connect the fifth scan signal line formed later with the fifth scan connection line 65-1 through this via.

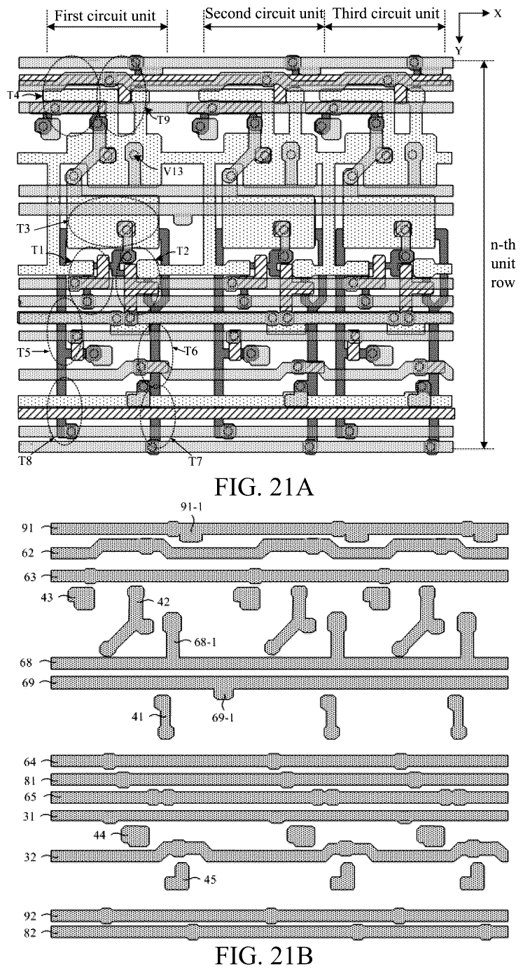

(25) A pattern of a third conductive layer is formed. In an exemplary implementation, forming the third conductive layer may include: a third conductive thin film is deposited on the substrate on which the aforementioned patterns are formed, the third conductive thin film is patterned through a patterning process to form a third conductive layer disposed on the fourth insulation layer, as shown in FIGS. 21A and 21B, wherein FIG. 21B is a schematic diagram of the third conductive layer in FIG. 21A.

In an exemplary implementation, each of patterns of third conductive layers of a plurality of circuit units in the display substrate may include a first connection electrode 41, a second connection electrode 42, a third connection electrode 43, a fourth connection electrode 44, a fifth connection electrode 45, a first light emitting signal line 31, a second light emitting signal line 32, a second scan signal line 62, a third scan signal line 63, a fourth scan signal line 64, a fifth scan signal line 65, a first power supply connection line 68, a second power supply connection line 69, a first initial signal line 81, a second initial signal line 82, a first reference signal line 91, and a second reference signal line 92.

In an exemplary implementation, each of shapes of the first light emitting signal line 31, the second light emitting signal line 32, the second scan signal line 62, the third scan signal line 63, the fourth scan signal line 64, the fifth scan signal line 65, the first power supply connection line 68, the second power supply connection line 69, the first initial signal line 81, the second initial signal line 82, the first reference signal line 91, and the second reference signal line 92 may be a shape of line in which a main portion extends along the first direction X. The second scan signal line 62, the third scan signal line 63, and the first reference signal line 91 may be located on a side opposite to the fourth plate 74 in the second direction Y, the first light emitting signal line 31, the second light emitting signal line 32, the fourth scan signal line 64, the fifth scan signal line 65, the first initial signal line 81, the second initial signal line 82, and the second reference signal line 92 may be located on a side of the third plate 73 in the second direction Y, the first power supply connection line 68 may be located in a region where the fourth plate 74 is located, the second power supply connection line 69 may be located in a region where the third plate 73 is located, and the second power supply connection line 69 may be located on a side of the first power supply connection line 68 in the second direction Y.

In an exemplary implementation, the third scan signal line 63 may be located on a side opposite to the fourth plate 74 in the second direction Y, the second scan signal line 62 may be located on a side opposite to the third scan signal line 63 in the second direction Y, and first reference signal line 91 may be located on a side opposite to the second scan signal line 62 in the second direction Y.

In an exemplary implementation, the fourth scan signal line 64 may be located on a side of the third plate 73 in the second direction Y, the first initial signal line 81 may be located on a side of the fourth scan signal line 64 in the second direction Y, the fifth scan signal line 65 may be located on a side of the first initial signal line 81 in the second direction Y, the first light emitting signal line 31 may be located on a side of the fifth scan signal line 65 in the second direction Y, the second light emitting signal line 32 may be located on a side of the first light emitting signal line 31 in the second direction Y, the second reference signal line 92 may be located on a side of the second light emitting signal line 32 in the second direction Y, and the second initial signal line 82 may be located on a side of the second reference signal line 92 in the second direction Y.

In an exemplary implementation, the first power supply connection line 68 may be located on a side of the fourth plate 74 close to the third plate 73, an orthographic projection of the first power supply connection line 68 on the substrate is overlapped, at least partially, with an orthographic projection of the fourth plate 74 on the substrate, and the first power supply connection line 68 is configured to connect with a first power supply line formed later to form a high-voltage power supply grid structure in a mesh communication structure in the display substrate.

In an exemplary implementation, the second power supply connection line 69 may be located on the side of the third plate 73 close to the fourth plate 74, an orthographic projection of the second power supply connection line 69 on the substrate is overlapped, at least partially, with the orthographic projection of the third plate 73 on the substrate, and the second power supply connection line 69 is configured to connect with a second power supply line formed later to form a lower-voltage power supply grid structure in a mesh communication structure in the display substrate.

In the exemplary embodiment, a shape of the first light emitting signal line 31 may be a shape of straight line in which a main portion extends along the first direction X, and the first light emitting signal line 31 is connected with a fifth gate electrode 25 of each circuit unit through the seventeenth via V17, thereby achieving that the first light emitting signal line 31 is connected to the fifth gate electrode 25 of the fifth transistor T5, and the first light emitting signal line 31 can control turn-on and turn-off of the fifth transistor T5.

In the exemplary embodiment, a shape of the second light emitting signal line 32 may be a shape of straight line in which a main portion extends along the first direction X, and the second light emitting signal line 32 is connected with a sixth gate electrode 26 of each circuit unit through the eighteenth via V18, thereby achieving that the second light emitting signal line 32 is connected to a sixth gate electrode 26 of the sixth transistor T6, and the second light emitting signal line 32 can control turn-on and turn-off of the sixth transistor T6.

In an exemplary implementation, a shape of the second scan signal line 62 may be a shape of polyline extending along the first direction X, an orthographic projection of the second scan signal line 62 on the substrate is overlapped, at least partially, with the orthographic projection of the second scan connection line 62-1 on the substrate, and the second scan signal line 62 is connected with the second scan connection line 62-1 through the twenty-third via V23. The second scan signal line 62 may serve as an upper layer signal line of the second scan signal line in the double-layer structure, and the second scan connection line 62-1 located in the first conductive layer and the second scan signal line 62 located in the third conductive layer form the second scan signal lines in the double-layer structure, thereby achieving that the second scan signal line is connected to the gate electrode of the ninth transistor T9, and the second scan signal line can control turn-on and turn-off of the ninth transistor T9.

In an exemplary implementation, a shape of the third scan signal line 63 may be a shape of straight line in which a main portion extends along the first direction X, the third scan signal line 63 is connected with a fourth gate electrode 24 in each circuit unit through the sixteenth via V16, thereby the third scan signal line 63 being connected to a fourth gate electrode 24 of the fourth transistor T4 is achieved, and the third scan signal line 63 can control turn-on and turn-off of the fourth transistor T4.

In an exemplary implementation, a shape of the fourth scan signal line 64 may be a shape of straight line in which a main portion extends along the first direction X, the fourth scan signal line 64 is connected with a first gate electrode 21 in each circuit unit through the fourteenth via V14, thereby the fourth scan signal line 64 being connected to a first gate electrode 21 of the first transistor T1 is achieved, and the fourth scan signal line 64 can control turn-on and turn-off of the first transistor T1.

In an exemplary implementation, a shape of the fifth scan signal line 65 may be a shape of line extending along the first direction X, an orthographic projection of the fifth scan signal line 65 on the substrate is overlapped, at least partially, with the orthographic projection of the fifth scan connection line 65-1 on the substrate. On one hand, the fifth scan signal line 65 is connected with the second gate electrode 22 through the fifteenth via V15. On the other hand, the fifth scan signal line 65 is connected with the fifth scan connection line 65-1 through the twenty-fourth via V24. The fifth scan signal line 65 may serve as an upper layer signal line of the fifth scan signal lines in the double-layer structure, and the fifth scan connection line 65-1 located in the second conductive layer and the fifth scan signal line 65 located in the third conductive layer form the fifth scan signal lines in the double-layer structure, thereby achieving that the fifth scan signal line is connected to a second gate electrode 22 of the second transistor T2, and the second scan signal line can control turn-on and turn-off of the second transistor T2.

In an exemplary implementation, the second scan signal line 62 and the fifth scan signal line 65 may be connected with a same gate drive circuit after extending to a bezel region, so as to achieve output of a same scan signal. That is, the second scan signal line 62 and the fifth scan signal line 65 output a same second scan signal.

In the present disclosure, by providing the second scan signal line and the fifth scan signal line in the double-layer structure, resistance of the signal line can be effectively reduced, which effectively reduces voltage drop of a scanning signal, improves uniformity of the panel, avoids poor display of the display substrate, and ensures a display effect of the display substrate.

In an exemplary implementation, a shape of the first power supply connection line 68 may be a shape of straight line in which a main portion extends along the first direction X, and the first power supply connection line 68 is connected with a fourth plate 74 in each circuit unit through the thirteenth via V13, thus connection of the first power supply connection line 68 to the fourth plate 74 is achieved. Since the first power supply connection line 68 is connected with the first power supply line formed later, the first power supply connection line 68 can write a first power supply signal to the upper plate of the second storage capacitor.

In an exemplary implementation, a first power supply connection block 68-1 is provided on a side of the first power supply connection line 68 away from the second power supply connection line 69, a first end of the first power supply connection block 68-1 is connected with the first power supply connection line 68, and a second end of the first power supply connection block 68-1 extends toward a direction away from the second power supply connection line 69. In an exemplary implementation, on the one hand, the first power supply connection block 68-1 is configured to connect with the fourth plate 74 through the thirteenth via V13. On the other hand, the first power supply connection block 68-1 is configured to connect with the first power supply line formed later.

In an exemplary implementation, in at least one circuit unit, a second power supply connection block 69-1 is provided on a side of the second power supply connection line 69 away from the first power supply connection line 68. A first end of the second power supply connection block 69-1 is connected with the second power supply connection line 69, a second end of the second power supply connection block 69-1 extends in a direction away from the first power supply connection line 68, and the second power supply connection block 69-1 is configured to connect with the second power supply line formed later. In an exemplary implementation, the second power supply connection block 69-1 may be disposed between the first circuit unit and the second circuit unit.

In an exemplary implementation, a shape of the first initial signal line 81 may be a shape of straight line in which a main portion extends along the first direction X, the first initial signal line 81 is connected with a first region of a first active layer in each circuit unit through the first via V1, thereby the first initial signal line 81 being connected to a first electrode of the seventh transistor T1 is achieved, and the first initial signal line 81 can write the first initial signal to the first electrode of the first transistor T1.

In an exemplary implementation, a shape of the second initial signal line 82 may be a shape of straight line in which a main portion extends along the first direction X, the second initial signal line 82 is connected with a first region of a seventh active layer in each circuit unit through the seventh via V7, thereby the second initial signal line 82 being connected to a first electrode of the seventh transistor T7 is achieved, and the second initial signal line 82 can write the second initial signal to the first electrode of the seventh transistor T7.

In an exemplary implementation, a shape of the first reference signal line 91 may be a shape of straight line in which a main portion extends along the first direction X, the first reference signal line 91 is connected with a first region of a ninth active layer in each circuit unit through the ninth via V9, thereby the first reference signal line 91 being connected to a first electrode of the ninth transistor T9 is achieved, and the first reference signal line 91 can write the first reference signal to the first electrode of the ninth transistor T9.

In an exemplary implementation, a reference connection block 91-1 is provided on a side of the first reference signal line 91 close to the second scan signal line 62, a first end of the reference connection block 91-1 is connected with the first reference signal line 91, a second end of the reference connection block 91-1 extends in a direction toward the second scan signal line 62, and the reference connection block 91-1 is configured to connect with a reference signal connection line formed later.

In an exemplary implementation, a shape of the second reference signal line 92 may be a shape of straight line in which a main portion extends along the first direction X, the second reference signal line 92 is connected with a first region of a ninth active layer in each circuit unit through the eighth via V8, thereby the second reference signal line 92 being connected to a first electrode of the ninth transistor T8 is achieved, and a second reference signal line 92 in the n-th unit row can write the second reference signal to a first electrode of an eighth transistor T8 in the n-th unit row.

In an exemplary implementation, a shape of the first connection electrode 41 may be a shape of strip in which a main portion extends along the second direction Y, and the first connection electrode 41 may be located between the fourth scan signal line 64 and the second power supply connection line 69. A first end of the first connection electrode 41 is connected with a second region of the first active layer (i.e., a first region of the second active layer) through the second via V2, and a second end of the first connection electrode 41 is connected with the first plate 71 through the tenth via V10. In an exemplary implementation, the first connection electrode 41 enables the second electrode of the first transistor T1, the first electrode of the second transistor T2, the gate electrode of the third transistor T3, and the first plate 71 of the first storage capacitor (i.e., a first end of the first storage capacitor) being at a same potential, and the first connection electrode 41 may serve as the first node N1 of the pixel drive circuit.

In an exemplary implementation, a shape of the second connection electrode 42 may be a shape of polyline in which a main portion extends along the second direction Y, and the second connection electrode 42 may be located between the third scan signal line 63 and the first power supply connection line 68. A first end of the second connection electrode 42 is connected with a second region of the fourth active layer (i.e., a second region of the ninth active layer) through the fourth via V4, a second end of the second connection electrode 42 is connected with the first plate connection line 73-1 through the twelfth via V12, and a third end between the first end and the second end is connected with the second plate 72 through the eleventh via V11. In an exemplary implementation, the second connection electrode 42 enables the second electrode of the fourth transistor T4, the second electrode of the ninth transistor T9, the third plate 73 of the first storage capacitor (i.e., a second end of the first storage capacitor) and the second plate 72 of the second storage capacitor (i.e., a second end of the second storage capacitor) being at a same potential, and the second connection electrode 42 may serve as the fifth node N5 of the pixel drive circuit.

In an exemplary implementation, a shape of the third connection electrode 43 may be rectangular, the third connection electrode 43 may be located between the third scan signal line 63 and the first power supply connection line 68, and the third connection electrode 43 is connected with the first region of the fourth active layer through the third via V3. In an exemplary implementation, the third connection electrode 43 may serve as a first electrode of the fourth transistor T4, and is configured to connect with a data signal line formed later.

In an exemplary implementation, a shape of the fourth connection electrode 44 may be rectangular, the fourth connection electrode 44 may be located between the first light emitting signal line 31 and the second light emitting signal line 32, and the fourth connection electrode 44 is connected with a first region of the fifth active layer through the fifth via V5. In an exemplary implementation, the fourth connection electrode 44 may serve as a first electrode of the fifth transistor T5, and is configured to connect with the first power supply line formed later.

In an exemplary implementation, a shape of the fifth connection electrode 45 may be “L” shaped, the fifth connection electrode 45 may be located between the second light emitting signal line 32 and the second reference signal line 92, and the fifth connection electrode 45 is connected with a second region of the sixth active layer (i.e., a second region of the seventh active layer) through the sixth via V6. In an exemplary implementation, the fifth connection electrode 45 may serve as a second electrode of the sixth transistor T6 and a second electrode of the seventh transistor T7, and the fifth connection electrode 45 is configured to connect with an anode connection electrode formed later.

Different from the foregoing embodiments, the first light emitting signal line 31, the second light emitting signal line 32, and the second reference signal line 92 are disposed in the third conductive layer in this embodiment. On the one hand, the second reference signal line 92 in the third conductive layer is provided between the first scan signal line 61 and the second initial signal line 82, so that the second reference signal line 92 is wired nearby the eighth transistor T8, which simplifies the connection structure. On the other hand, the first reference signal line 91 is disposed on a side of the second scan signal line 62 away from the second storage capacitor, the second scan signal line 62 is disposed on a side of the third scan signal line 63 away from the second storage capacitor. That is, the second scan signal line 62 is disposed above the third scan signal line 63, and the first reference signal line 91 is disposed above the second scan signal line 62, so that a wiring layout is more reasonable.

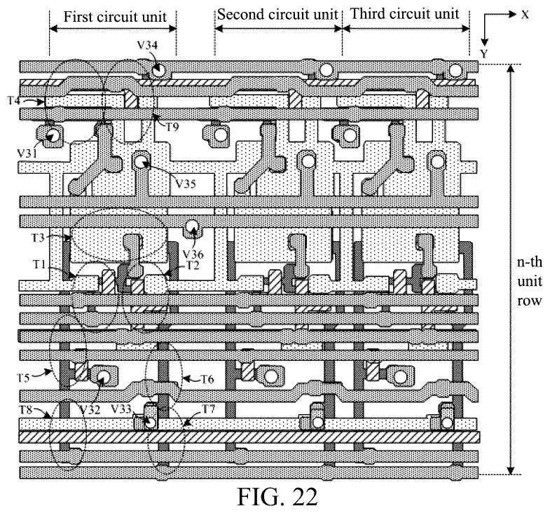

(26) A pattern of a fifth insulation layer is formed. In an exemplary implementation, forming the pattern of the fifth insulation layer may include: a fifth insulation thin film is deposited on the substrate on which the aforementioned patterns are formed, the fifth insulation thin film is patterned through a patterning process to form a fifth insulation layer that covers the third conductive layer, wherein a plurality of vias are disposed on each circuit unit, as shown in FIG. 22.

In an exemplary implementation, a plurality of vias of each circuit unit in the display substrate includes, at least, a thirty-first via V31, a thirty-second via V32, a thirty-third via V33, a thirty-fourth via V34, and a thirty-fifth via V35.

In an exemplary implementation, an orthographic projection of the thirty-first via V31 on the substrate is located within a range of an orthographic projection of the third connection electrode 43 on the substrate, a fifth insulation layer within the thirty-first via V31 is removed to expose a surface of the third connection electrode 43, and the thirty-first via V31 is configured such that the data signal line formed later is connected with the third connection electrode 43 through this via.

In an exemplary implementation, an orthographic projection of the thirty-second via V32 on the substrate is located within a range of an orthographic projection of the fourth connection electrode 44 on the substrate, a fifth insulation layer within the thirty-second via V32 is removed to expose a surface of the fourth connection electrode 44, and the thirty-second via V32 is configured such that the first power supply line formed later is connected with the fourth connection electrode 44 through this via.

In an exemplary implementation, an orthographic projection of the thirty-third via V33 on the substrate is located within a range of an orthographic projection of the fifth connection electrode 45 on the substrate, a fifth insulation layer within the thirty-third via V33 is removed to expose a surface of the fifth connection electrode 45, and the thirty-third via V33 is configured such that the anode connection electrode formed later is connected with the fifth connection electrode 45 through this via.

In an exemplary implementation, an orthographic projection of the thirty-fourth via V34 on the substrate is within a range of an orthographic projection of the reference connection block 91-1 of the first reference signal line 91 on the substrate. A fifth insulation layer within the thirty-fourth via V34 is removed to expose a surface of the reference connection block 91-1, and the thirty-fourth via V34 is configured such that the reference signal connection line formed later is connected with the reference connection block 91-1 through this via.

In an exemplary implementation, an orthographic projection of the thirty-fifth via V35 on the substrate is within a range of an orthographic projection of the first power supply connection block 68-1 of the first power supply connection line 68 on the substrate, a fifth insulation layer within the thirty-fifth via V35 is removed to expose a surface of the first power supply connection block 68-1, and the thirty-fifth via V35 is configured such that the first power supply line formed later is connected with the first power supply connection block 68-1 through this via.

In an exemplary implementation, the at least one circuit unit may further include a thirty-sixth via V36. An orthographic projection of the thirty-fifth via V36 on the substrate is within a range of an orthographic projection of the second power supply connection block 69-1 of the second power supply connection line 69 on the substrate, a fifth insulation layer within the thirty-sixth via V36 is removed to expose a surface of the second power supply connection block 69-1, and the thirty-sixth via V36 is configured such that the second power supply line formed later is connected with the second power supply connection block 69-1 through this via. In an exemplary implementation, the thirty-sixth via V36 may be located between the first circuit unit and the second circuit unit.

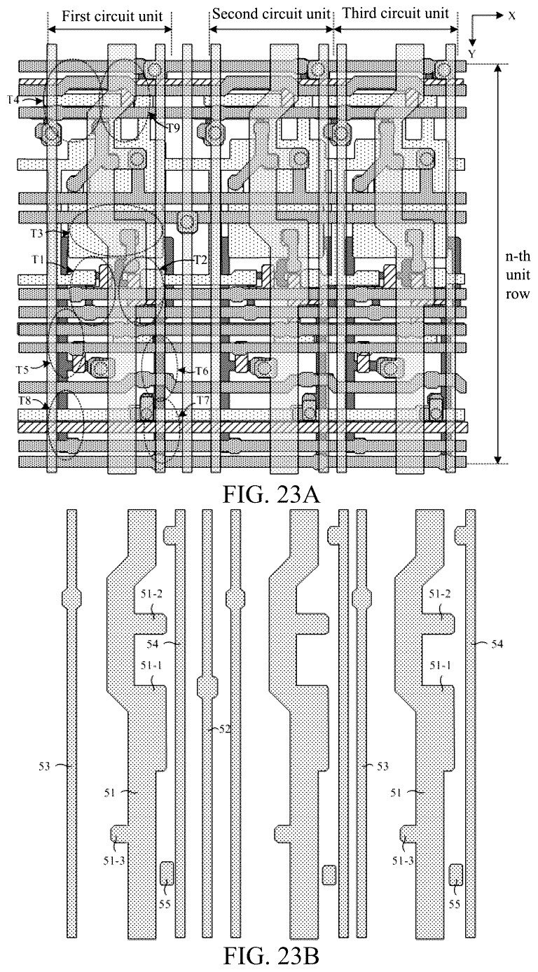

(27) A pattern of a fourth conductive layer is formed. In an exemplary implementation, forming the pattern of the fourth conductive layer may include: a fourth conductive thin film is deposited on the substrate on which the aforementioned patterns are formed, the fourth conductive thin film is patterned through a patterning process to form a fourth conductive layer disposed on the fifth insulation layer, as shown in FIGS. 23A and 23B, wherein FIG. 23B is a schematic diagram of the fourth conductive layer in FIG. 23A.

In an exemplary implementation, each of patterns of fourth conductive layers of a plurality of circuit units in the display substrate may include a first power supply line 51, a data signal line 53, a reference signal connection line 54, and an anode connection electrode 55.

In an exemplary implementation, each of shapes of the first power supply line 51, the data signal line 53, and the reference signal connection line 54 may be a shape of strip in which a main portion extends along the second direction Y, the first power supply line 51 may be located on a side of the data signal line 53 in the first direction X, and the reference signal connection line 54 may be located on a side of the first power supply line 51 in the first direction X. That is, the first power supply line 51 may be located between the data signal line 53 and the reference signal connection line 54.

In an exemplary implementation, a shape of the first power supply line 51 may be a shape of polyline in which a main portion extending along the second direction Y. On one hand, the first power supply line 51 is connected with the fourth connection electrode 44 through the thirty-second via V32, and on the other hand, the first power supply line 51 is connected with the second power supply connection electrode 68-1 through the thirty-fifth via V35. Since the fourth connection electrode 44 is connected with the first region of the fifth active layer through a via, writing of the first power supply signal to the first electrode of the fifth transistor T5 by the first power supply line 51 is achieved. Since the first power supply connection block 68-1 is connected with the first power supply connection line 68, the first power supply connection line 68 in which a main portion extends along the first direction X and the first power supply line 51 in which a main portion extends along the second direction Y are connected to each other, so that the first power supply line 51 and the first power supply connection line 68 form a mesh structure for transmitting the first power supply signal in the display substrate, which can not only effectively reduce a resistance of the first power supply line 51 and reduce the voltage drop of the first power supply signal, but also effectively improve uniformity of the first power supply signal in the display substrate, effectively improve display uniformity and improve the display quality.

In an exemplary implementation, a power supply shield block 51-1 is provided on a side of the first power supply line 51 close to the reference signal connection line 54, a first end of the power supply shield block 51-1 is connected with the first power supply line 51, and a second end of the power supply shield block 51-1 extends in a direction toward the reference signal connection line 54. A shape of the power supply shield block 51-1 may be rectangular, and an orthographic projection of the power supply shield block 51-1 on the substrate is overlapped, at least partially, with an orthographic projection of the first connection electrode 41 on the substrate. Since the first connection electrode 41 serves as the first node N1 in the pixel drive circuit, the power supply shield block 51-1 which is at a constant voltage can effectively shield an influence of other signals in the pixel drive circuit on the first node N1, thereby avoiding an influence of other signals (such as the data voltage jump) on a potential at the first node N1 in the pixel drive circuit, and improving the display effect.

In an exemplary implementation, the orthographic projection of the power supply shield block 51-1 on the substrate may include the orthographic projection of the first connection electrode 41 on the substrate.

In an exemplary implementation, a first power supply connection block 51-2 is provided on the side of the first power supply line 51 close to the reference signal connection line 54, a first end of the first power supply connection block 51-2 is connected with the first power supply line 51, a second end of the first power supply connection block 51-2 is connected to the first power supply connection block 68-1 through the thirty-fifth via V35 after extending toward the reference signal connection line 54.

In an exemplary implementation, a second power supply connection block 51-3 is provided on a side of the first power supply line 51 close to the data signal line 53, a first end of the second power supply connection block 51-3 is connected with the first power supply line 51, a second end of the second power supply connection block 51-3 is connected with the fourth connection electrode 44 through the thirty-second via V32 after extending toward the data signal line 53.

In an exemplary implementation, the first power supply line 51, the power supply shield block 51-1, the first power supply connection block 51-2, and the second power supply connection block 51-3 may be connected to each other to form an integral structure.

In an exemplary implementation, an orthographic projection of the first power supply line 51 on the substrate is overlapped, at least partially, with an orthographic projection of the second connection electrode 42 on the substrate. Since the second connection electrode 42 serves as the fifth node N5 in the pixel drive circuit, the first power supply line 51 which is at a constant voltage can effectively shield an influence of other signals in the pixel drive circuit on the fifth node N5, thereby avoiding an influence of other signals on a potential at the fifth node N5 in the pixel drive circuit, and improving the display effect.

In an exemplary implementation, the first power supply line 51 may be of an unequal width design, and the first power supply line 51 with the unequal width design can not only facilitate a layout of a pixel structure, but also reduce a parasitic capacitance between the first power supply line and the data signal line.

In an exemplary implementation, a shape of the data signal line 53 may be a shape of straight line in which a main portion extends along the second direction Y, and the data signal line 53 is connected with the third connection electrode 43 through the thirty-first via V31. Since the third connection electrode 43 is connected with the first region of the fourth active layer through a via, writing of the data signal to the first electrode of the fourth transistor T4 by the data signal line 53 is achieved.

In an exemplary implementation, the shape of the reference signal connection line 54 may be the shape of straight line in which the main portion extends along the second direction Y, and the reference signal connection line 54 is connected with the reference connection block 91-1 through the thirty-fourth via V34. Since the reference connection block 91-1 is connected with the first reference signal line 91, the first reference signal line 91 in which a main portion extends along the first direction X and the reference signal connection line 54 in which a main portion extends along the second direction Y are connected to each other, so that the first reference signal line 91 and the reference signal connection line 54 form the mesh structure for transmitting the first reference signal in the display substrate, which can not only effectively reduce the resistance of the first reference signal line and reduce a voltage drop of the first reference signal, but also effectively improve uniformity of the first reference signal in the display substrate, effectively improve the display uniformity and improve the display quality.

In an exemplary implementation, a shape of the anode connection electrode 55 may be rectangular, and the anode connection electrode 55 is connected with the fifth connection electrode 45 through the thirty-third via V33. Since the fifth connection electrode 45 is connected with the second region of the sixth active layer (i.e., the second region of the seventh active layer) through a via, the anode connection electrode 55 being connected with the second electrode of the sixth transistor T6 and the second electrode of the seventh transistor T7 is achieved. In an exemplary implementation, the anode connection electrode 55 is configured to connect with the anode formed later, thereby the pixel drive circuit can drive a light emitting device.

In an exemplary implementation, the at least one circuit unit may further include a second power supply line 52. A shape of the second power supply line 52 may be a shape of straight line in which a main portion extends along the second direction Y, and the second power supply line 52 is connected with the second power supply connection block 69-1 through the thirty-sixth via V36. Since the second power supply connection block 69-1 is connected with the second power supply connection line 69, the second power supply connection line 69 in which a main portion extends along the first direction X and the second power supply line 52 in which a main portion extends along the second direction Y are connected to each other, so that the second power supply line 52 and the second power supply connection line 69 form the mesh structure for transmitting the second power supply signal in the display substrate, which can not only effectively reduce a resistance of the second power supply line 52 and reduce a voltage drop of the second power supply signal, but also effectively improve uniformity of the second power supply signal in the display substrate, effectively improve display uniformity and improve the display quality. In an exemplary implementation, the second power supply line 52 may be located between a reference signal connection line 54 of the first circuit unit and a data signal line 53 of the second circuit unit.

In an exemplary implementation, the first power supply connection line 68 of the third conductive layer may be disposed in each unit row, and the first power supply line 51 of the fourth conductive layer may be disposed in each unit column, and a plurality of first power supply connection lines 51 are connected, respectively, to a plurality of first power supply connection lines 68 to form the mesh structure for transmitting the first power supply signal.

In an exemplary implementation, the first reference signal line 91 of the third conductive layer may be disposed in each unit row, the reference signal connection line 54 of the fourth conductive layer may be disposed in each unit column, and a plurality of first reference signal lines 91 are connected, respectively, to a plurality of reference signal connection lines 54 to form the mesh structure for transmitting the first reference signal.

In an exemplary embodiment, the second power supply connection line 69 of the third conductive layer may be disposed in each unit row, and the second power supply lines 52 of the fourth conductive layer may be disposed every two unit columns, and a plurality of the second power supply connection lines 52 are connected, respectively, to a plurality of the second power supply connection lines 69 to form the mesh structure for transmitting the second power supply signal.

A subsequent manufacturing process may include forming a pattern of a first planarization layer, the first planarization layer is provided with a plurality of anode vias, orthographic projections of the anode vias on the substrate are within a range of an orthographic projection of the anode connection electrode on the substrate. A first planarization layer within the anode vias is removed to expose a surface of the anode connection electrode, and the anode vias are configured such that the anode formed later is connected with the anode connection electrode through the anode vias.

At that point, the drive circuit layer in this embodiment is manufactured on the substrate. In an exemplary implementation, after the drive circuit layer is manufactured, a light emitting structure layer and an encapsulation structure layer may be sequentially manufactured on the drive circuit layer, which is not repeated here.

In an exemplary implementation, in a plane parallel to the display substrate, the drive circuit layer may include a plurality of circuit units, each of the circuit units may include a pixel drive circuit, and a first scan signal line, a second scan signal line, a third scan signal line, a fourth scan signal line, a fifth scan signal line, a first light emitting signal line, a second light emitting signal line, a first initial signal line, a second initial signal line, a first reference signal line, a second reference signal line, a first power supply line and a data signal line, which are connected with the pixel drive circuit. In a plane perpendicular to the display substrate, the drive circuit layer may include, at least, a first insulation layer, a semiconductor layer, a second insulation layer, a first conductive layer, a third insulation layer, a second conductive layer, a fourth insulation layer, a third conductive layer, a fifth insulation layer, and a fourth conductive layer, which are stacked sequentially on the substrate.

In an exemplary implementation, the substrate may be a flexible substrate, or a rigid substrate. The rigid substrate may be made of, but is not limited to, one or more of glass and quartz. The flexible substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be Polyimide (P1), Polyethylene Terephthalate (PET), or a surface-treated polymer soft film, or the like, materials of the first inorganic material layer and the second inorganic material layer may be Silicon Nitride (SiNx) or Silicon Oxide (SiOx), or the like, for improving a water and oxygen resistance capability of the substrate, and a material of the semiconductor layer may be amorphous silicon (a-si).

In an exemplary implementation, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The first insulation layer, the second insulation layer, the third insulation layer, the fourth insulation layer, and the fifth insulation layer may be made of any one or more of Silicon Oxide (SiOx), Silicon Nitride (SiNx), and Silicon Oxynitride (SiON), and may be a single layer, a multi-layer, or a composite layer. The first insulation layer is referred to as a buffer layer, the second insulation layer and the third insulation layer are referred to as gate insulation (GI) layers, the fourth insulation layer is referred to as an interlayer dielectric (ILD) layer, and the fifth insulation layer is referred to as a passivation (PVX) layer. The first planarization layer may be made through an organic material such as resin. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology.

In a display substrate, semiconductor layers in adjacent circuit units in a unit row are connected to each other. For example, first regions of a ninth active layer of a plurality of circuit units in a unit row are connected to each other by a first active connection line, and first regions of a seventh active layer of a plurality of circuit units in a unit row are connected to each other by a second active connection line, and each of shapes of the first active connection line and the second active connection line may be a shape of line extending along the first direction X. A study suggests that a first active connection line and a second active connection line affect an AA Hole structure of a display region, resulting in poor display of Hole Mura around the opening. In addition, the display substrate has a problem of severe voltage drop of the first power supply signal, the second power supply signal, and the reference signal.

In the embodiment of the present disclosure, by dividing the semiconductor layer of the circuit unit into the first active pattern and the second active pattern, the active layer of the transistor in the first active pattern and the active layer of the transistor in the second active pattern are not connected, and the semiconductor layers in the adjacent circuit units in the unit row and the unit column are isolated from each other, thereby eliminating the active connection line structure, which avoids an influence of the semiconductor layer on an opening structure of the display region, minimizes the poor display of Hole Mura, and improves the display quality and the display property.

In the embodiment of the present disclosure, by providing the first power supply connection line in which the main portion extends along the first direction X and the first power supply line in which the main portion extends along the second direction Y, and the first power supply connection line and the first power supply connection line are connected to each other, so that the first power supply line and the first power supply connection line form the mesh structure for transmitting the first power supply signal in the display substrate, which can not only effectively reduce the resistance of the first power supply line and reduce the voltage drop of the first power supply signal, but also effectively improve the uniformity of the first power supply signal in the display substrate, effectively improve the display uniformity and improve the display quality.

In the embodiment of the present disclosure, by providing the second power supply connection line in which the main portion extends along the first direction X and the second power supply line in which the main portion extends along the second direction Y, and the second power supply connection line and the second power supply connection line are connected to each other, so that the second power supply line and the second power supply connection line form a mesh structure for transmitting the second power supply signal in the display substrate, which can not only effectively reduce the resistance of the second power supply signal line and reduce the voltage drop of the second power supply signal, but also effectively improve the uniformity of the second power supply signal in the display substrate, effectively improve the display uniformity and the display quality.

In the embodiment of the present disclosure, by providing the first reference signal line in which the main portion extends along the first direction X and the reference signal connection line in which the main portion extends along the second direction Y, and the first reference signal line and the reference signal connection line are connected to each other, so that the first reference signal line and the reference signal connection line form the mesh structure for transmitting the first reference signal in the display substrate, which can not only effectively reduce the resistance of the first reference signal line and reduce the voltage drop of the first reference signal, but also effectively improve uniformity of the first reference signal in the display substrate, effectively improve the display uniformity and improve the display quality.

In the embodiment of the present disclosure, by providing the first shield electrode, the second shield electrode the third shield electrode, and the fourth shield electrode, the influence of data voltage jump on the first transistor T1, the second transistor T2, the fourth transistor T4, the ninth transistor T9 and the fifth node N5 can be shielded, thus avoiding the influence of data voltage jump on the normal operation of the pixel drive circuit, and improving the display effect.

In the embodiment of present disclosure, by providing the second shield electrode and the semiconductor layer to form the additional capacitor of the second storage capacitor, a total capacity of the second storage capacitor can be effectively increased, which improves an operating performance of the pixel drive circuit, and improves the display effect.

In the embodiment of the present disclosure, by providing the second scan signal line and the fifth scan signal line in the double-layer structure, resistance of the signal line can be effectively reduced, which effectively reduces voltage drop of a scanning signal, improves uniformity of the panel, avoids poor display of the display substrate, and ensures the display effect of the display substrate.

In the embodiment of the present disclosure, the first node N1 and the fifth node N5 are shielded by providing the first power supply line and the power supply shield block, which effectively avoids other signals affecting the potentials of the first node N1 and the fifth node N5 of the pixel drive circuit and improves the display effect.

The manufacturing process in the present disclosure may be compatible well with an existing manufacturing process, is simple in process implementation, is easy to implement, and has a high production efficiency, a low production cost, and a high yield.

The structure shown and mentioned above in the present disclosure and the manufacturing process therefor are merely an exemplary description. In an exemplary implementation, the corresponding structures may be altered and the patterning processes may be added or reduced according to actual needs. For example, the second scan signal line and the fifth scan signal line in the display substrate shown in FIG. 5 may be in a double-layer structure. As another example, one or more of the first scan signal line, the third scan signal line, and the fourth scan signal line in the display substrate may be in a double-layer structure. For another example, the reference signal connection line in the fourth conductive layer may be connected with the second reference signal line, so that the second reference signal line and the reference signal connection line form a mesh structure for transmitting the second reference signal in a mesh shape in the display substrate. For another example, the second power supply line in the fourth conductive layer may be altered to an initial connection line, and the initial connection line may be connected with the first initial signal line or the second initial signal line such that the first initial signal line and the initial connection line form a mesh structure for transmitting the first initial signal in the display substrate, or the second initial signal line and the initial connection line form a mesh structure for transmitting the second initial signal in the display substrate, which is not limited here in the present disclosure.

In an exemplary implementation, the display substrate according to the present disclosure may be applied to a display apparatus with a pixel drive circuit, such as an OLED, a quantum dot display (QLED), a light emitting diode display (Micro LED or Mini LED), or a Quantum Dot Light Emitting Diode display (QDLED), which is not limited here in the present disclosure.

The present disclosure also provides a method for manufacturing a display substrate, for manufacturing the display substrate according to the foregoing embodiments.

In an exemplary embodiment, the display substrate includes a plurality of circuit units forming a plurality of unit rows and a plurality of unit columns, wherein at least one circuit unit includes a pixel drive circuit at least including a plurality of transistors. The method for manufacturing a display substrate may include:

forming a semiconductor layer on a substrate, and a plurality of conductive layers disposed on a side of the semiconductor layer away from the substrate wherein the semiconductor layer at least includes active layers of a plurality of transistors, the semiconductor layer includes at least a first active pattern and a second active pattern, the first active pattern includes an active layer of at least one transistor, and the second active pattern includes an active layer of at least one transistor, the second active pattern including an active layer of at least one transistor. In at least one circuit unit, the first active pattern is spaced from the second active pattern, the active layers of the plurality of transistors in the circuit unit are spaced from active layers of a plurality of transistors in a circuit unit adjacent in a unit row direction, and the active layers of the plurality of transistors in the circuit unit are spaced from active layers of a plurality of transistors in a circuit unit adjacent in a unit column direction.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate comprising a plurality of circuit units forming a plurality of unit rows and a plurality of unit columns, wherein
at least one circuit unit comprises a pixel drive circuit comprising at least a plurality of transistors;
in a plane perpendicular to the display substrate, at least one circuit unit comprises a semiconductor layer disposed on a substrate and a plurality of conductive layers disposed on a side of the semiconductor layer away from the substrate, the semiconductor layer at least comprises active layers of a plurality of transistors, the semiconductor layer at least comprises a first active pattern and a second active pattern, the first active pattern comprises an active layer of at least one transistor, the second active pattern comprises an active layer of at least one transistor; and
in at least one circuit unit, the first active pattern is spaced from the second active pattern, active layers of a plurality of transistors in the circuit unit are spaced from active layers of a plurality of transistors in a circuit unit adjacent in a unit row direction, and active layers of a plurality of transistors in the circuit unit are spaced from active layers of a plurality of transistors in a circuit unit adjacent in a unit column direction.

2. The display substrate of claim 1, wherein the first active pattern comprises active layers of two transistors, and the active layers of the two transistors are connected to each other to form an integral structure; the second active pattern comprises active layers of seven transistors, and the active layers of the seven transistors are connected to each other to form an integral structure.

3. The display substrate of claim 2, wherein
the pixel drive circuit comprises a first transistor and a seventh transistor as initialization transistors, a second transistor as a compensation transistor, a third transistor as a drive transistor, a fourth transistor as a data writing transistor, a fifth transistor and a sixth transistor as light emitting transistors, and an eighth transistor and a ninth transistor as reference transistors; and
the first active pattern comprises an active layer of the fourth transistor and an active layer of the ninth transistor, and the second active pattern comprises active layers of the first to third transistors and active layers of the fifth to eighth transistors.

4. The display substrate of claim 3, wherein
the pixel drive circuit further comprises a first storage capacitor and a second storage capacitor;
the first storage capacitor at least comprises a first plate and a third plate, an orthographic projection of the first plate on the substrate is overlapped, at least partially, with an orthographic projection of the third plate on the substrate;
the second storage capacitor at least comprises a second plate and a fourth plate, an orthographic projection of the second plate on the substrate is overlapped, at least partially, with an orthographic projection of the fourth plate on the substrate;
the first plate serves as a gate electrode of the third transistor, the second plate is connected with the third plate, and the fourth plate is connected with a first power supply line.

5. The display substrate of claim 4, wherein
the plurality of conductive layers at least comprise a first conductive layer, a second conductive layer, a third conductive layer, and a fourth conductive layer disposed sequentially along a direction away from the substrate;
the first plate and the second plate are disposed in the first conductive layer, the third plate and the fourth plate are disposed in the second conductive layer, the first power supply line is disposed in the fourth conductive layer, and the second plate is connected with the third plate through a connection electrode disposed in the third conductive layer.

6. The display substrate of claim 5, wherein the third plate is provided with a first plate connection line extending toward the fourth plate, the fourth plate is provided with a first groove recessed in a direction away from the third plate, the first plate connection line is disposed within the first groove, and an end of the first plate connection line away from the third plate is connected with the connection electrode through a via.

7. The display substrate of claim 5, wherein
the pixel drive circuit further comprises an additional capacitor, and a lower plate of the additional capacitor is disposed in the semiconductor layer,
an upper plate of the additional capacitor is disposed in the second conductive layer,
an orthographic projection of the upper plate on the substrate is overlapped, at least partially, with an orthographic projection of the lower plate on the substrate,
the lower plate is connected with the second plate, and
the upper plate is connected with the fourth plate.

8. The display substrate of claim 7, wherein
the lower plate comprises a second region of the active layer of the fourth transistor,
the second plate is connected with the second region of the active layer of the fourth transistor through the connection electrode disposed in the third conductive layer, and
the upper plate and the fourth plate are connected to each other to form an integral structure.

9. The display substrate of claim 3, wherein
a gate electrode of the first transistor is connected with a fourth scan signal line,
a gate electrode of the second transistor is connected with a fifth scan signal line,
a gate electrode of the fourth transistor is connected with a third scan signal line,
a gate electrode of the fifth transistor and a gate electrode of the sixth transistor are connected with a light emitting signal line,
a gate electrode of the seventh transistor and a gate electrode of the eighth transistor are connected with a first scan signal line,
a gate electrode of the ninth transistor is connected with a second scan signal line, and
the second scan signal line and the fifth scan signal line output a same scan signal.

10. The display substrate of claim 9, wherein
the display substrate further comprises a second scan connection line,
the second scan signal line and the second scan connection line are disposed in different conductive layers,
an orthographic projection of the second scan signal line on the substrate is overlapped, at least partially, with an orthographic projection of the second scan connection line on the substrate, and
the second scan signal line is connected with the second scan connection line through a via to form scan signal lines in a double-layer structure.

11. The display substrate of claim 10, wherein
the plurality of conductive layers at least comprise a first conductive layer, a second conductive layer, a third conductive layer, and a fourth conductive layer disposed sequentially along a direction away from the substrate;
the second scan connection line is disposed in the first conductive layer, and the second scan signal line is disposed in the third conductive layer.

12. The display substrate of claim 9, wherein
the display substrate further comprises a fifth scan connection line,
the fifth scan signal line and the fifth scan connection line are disposed in different conductive layers,
an orthographic projection of the fifth scan signal line on the substrate is overlapped, at least partially, with an orthographic projection of the fifth scan connection line on the substrate, and
the fifth scan signal line is connected with the fifth scan connection line through a via to form scan signal lines in a double-layer structure.

13. The display substrate of claim 12, wherein
the plurality of conductive layers at least comprise a first conductive layer, a second conductive layer, a third conductive layer, and a fourth conductive layer disposed sequentially along the direction away from the substrate;
the fifth scan connection line is disposed in the second conductive layer, and the fifth scan signal line is disposed in the third conductive layer.

14. The display substrate of claim 3, wherein
at least one circuit unit further comprises a first shield electrode,
an orthographic projection of the first shield electrode on the substrate is overlapped, at least partially, with an orthographic projection of a semiconductor layer between two gate electrodes of the first transistor on the substrate, and
the orthographic projection of the first shield electrode on the substrate is overlapped, at least partially, with an orthographic projection of a semiconductor layer between two gate electrodes of the second transistor on the substrate.

15. The display substrate of claim 3, wherein
at least one circuit unit further comprises a second shield electrode, and
an orthographic projection of the second shield electrode on the substrate is overlapped, at least partially, with orthographic projections of a second electrode of the fourth transistor and a second electrode of the ninth transistor on the substrate.

16. The display substrate of claim 3, wherein
at least one circuit unit further comprises a third shield electrode, and
an orthographic projection of the third shield electrode on the substrate is overlapped, at least partially, with an orthographic projection of a semiconductor layer between two gate electrodes of the fourth transistor on the substrate.

17. The display substrate of claim 3, wherein
at least one circuit unit further comprises a fourth shield electrode, and
an orthographic projection of the fourth shield electrode on the substrate is overlapped, at least partially, with an orthographic projection of a semiconductor layer between two gate electrodes of the ninth transistor on the substrate.

18. The display substrate of claim 1, wherein
the display substrate further comprises at least one first power supply connection line extending along the unit row direction, and at least one first power supply line extending along the unit column direction; and the first power supply line and the first power supply connection line are disposed in different conductive layers, and the first power supply line and the first power supply connection line are connected through a via to form a mesh structure for transmitting a first power supply signal; or
the display substrate further comprises at least one second power supply connection line extending along the unit row direction, and at least one second power supply line extending along the unit column direction; and the second power supply line and the second power supply connection line are disposed in different conductive layers, and the second power supply line and the second power supply connection line are connected through a via to form a mesh structure for transmitting a second power supply signal; or
the display substrate further comprises at least one reference signal connection line extending along the unit row direction, and at least one reference signal line extending along the unit column direction; and the reference signal line and the reference signal connection line are disposed in different conductive layers, and the reference signal connection line are connected with the reference signal line through a via to form a mesh structure for transmitting a reference signal.

19-20. (canceled)

21. A display apparatus, comprising the display substrate of claim 1.

22. A method for manufacturing a display substrate, wherein the display substrate comprises a plurality of circuit units forming a plurality of unit rows and a plurality of unit columns, at least one circuit unit comprises a pixel drive circuit, the pixel drive circuit at least comprises a plurality of transistors; the manufacturing method comprises:
forming a semiconductor layer on a substrate, and a plurality of conductive layers disposed on a side of the semiconductor layer away from the substrate, wherein
the semiconductor layer at least comprises active layers of a plurality of transistors, the semiconductor layer comprises at least a first active pattern and a second active pattern, the first active pattern comprises an active layer of at least one transistor, and the second active pattern comprises an active layer of at least one transistor; and
in at least one circuit unit, the first active pattern is spaced from the second active pattern, the active layers of the plurality of transistors in the circuit unit are spaced from active layers of a plurality of transistors in a circuit unit adjacent in a unit row direction, and the active layers of the plurality of transistors in the circuit unit are spaced from active layers of a plurality of transistors in a circuit unit adjacent in a unit column direction.
